(19) United States
(12) Patent Application Publication
(10) Pub. No.: US 2025/0069958 A1
(43) Pub. Date: Feb. 27, 2025

(54) DUAL BEAM SYSTEMS AND METHODS FOR DECOUPLING THE WORKING DISTANCE OF A CHARGED PARTICLE BEAM DEVICE FROM FOCUSED ION BEAM GEOMETRY INDUCED CONSTRAINTS

(71) Applicant: Carl Zeiss SMT GmbH, Oberkochen (DE)

(72) Inventors: Alex Buxbaum, San Ramon, CA (US); Ramani Pichumani, Paolo Alto, CA (US); Dmitry Klochkov, Schwaebisch- Gmuend (DE); Eugen Foca, Ellwangen (DE); Thomas Korb, Schwaebisch Gmuend (DE); Jens Timo Neumann, Aalen (DE)

(21) Appl. No.: 18/949,168

(22) Filed: Nov. 15, 2024

Related U.S. Application Data
(63) Continuation of application No. PCT/EP2023/025213, filed on May 5, 2023.
(60) Provisional application No. 63/365,548, filed on May 31, 2022.

(30) Foreign Application Priority Data
Jul. 14, 2022 (DE) 10 2022 117 601.0

(51) Int. Cl. H01L 21/66; H01J 37/147; H01J 37/20; H01J 37/26; H01J 37/28; H01J 37/305

(52) U.S. Cl. CPC H01L 22/20; H01J 37/1471; H01J 37/20; H01J 37/265; H01J 37/28; H01J 37/3053; H01J 2237/202; H01J 2237/31749

(57) ABSTRACT

A method comprises: providing FIB and CPB columns with FIB and CPB optical axes coinciding at a wafer surface; in the coincidence arrangement, removing a cross section surface layer of a measurement site of a wafer using the FIB column to make a new cross section accessible for imaging; reducing a working distance between the CPB imaging column and the wafer surface in a direction along the axis of the CPB imaging column; imaging the new cross section at the measurement site of the wafer with the CPB imaging column at the reduced working distance and thus not in the coincidence arrangement; and increasing the working distance between the CPB imaging column and the wafer surface in the direction along the axis of the CPB imaging column until the coincidence arrangement is reached.

### CROSS-REFERENCE TO RELATED APPLICATIONS

The present application is a continuation of, and claims benefit under 35 USC 120 to, international application No. PCT/EP2023/025213, filed May 5, 2023, which claims benefit under 35 USC § 119 (e) of U.S. Provisional Application No. 63/365,548, filed May 31, 2022, and which claims benefit under 35 USC 119 of German Application No. 10 2022 117 601.0, filed Jul. 14, 2022. The entire disclosure of each of these applications is incorporated by reference herein.

### FIELD

The present disclosure relates to dual beam devices and three-dimensional circuit pattern inspection by cross sectioning of inspection volumes.

### BACKGROUND

Semiconductor structures are amongst the finest man-made structures and suffer from different imperfections. Systems for quantitative 3D-metrology, defect-detection or defect review look for these imperfections. Fabricated semiconductor structures are typically based on prior knowledge. The semiconductor structures are usually manufactured from a sequence of layers being parallel to a substrate. For example, in a logic type sample, metal lines run parallel in metal layers or HAR (high aspect ratio) structures and metal vias run perpendicular to the metal layers. The angle between metal lines in different layers is either 0° or 90°. On the other hand, for VNAND type structures it is known that their cross-sections are circular on average.

A semiconductor wafer can have a diameter of for example 300 mm and include a plurality of several sites, so called dies, each comprising at least one integrated circuit pattern such as for example for a memory chip or for a processor chip. During fabrication, semiconductor wafers can run through about 1000 process steps, and within the semiconductor wafer, about 100 and more parallel layers are formed, comprising the transistor layers, the layers of the middle of the line, and the interconnect layers and, in memory devices, a plurality of 3D arrays of memory cells. Dimensions, shapes and placements of the semiconductor structures and patterns are subject to several influences. In manufacturing of 3D-Memory devices, the processes currently include etching and deposition. Other process steps such as the lithography exposure or implantation also can have an impact on the properties of the IC-elements.

The aspect ratio and the number of layers of integrated circuits generally constantly increases and the structures are growing into 3^{rd} (vertical) dimension. The current height of the memory stacks exceeds a dozen of microns. In contrast, the features size is becoming smaller. The minimum feature size or critical dimension is below 10 nanometers (nm), for example 7 nm or 5 nm, and will approach feature sizes below 3 nm in near future. While the complexity and dimensions of the semiconductor structures are growing into the third dimension, the lateral dimensions of integrated semiconductor structures are becoming smaller. Therefore, measuring the shape, dimensions and orientation of the features and patterns in 3D and their overlay with high precision can become challenging.

With the desire for increasing the resolution of charged particle imaging systems in three dimensions, the inspection and 3D analysis of integrated semiconductor circuits in wafers can become more and more challenging. The lateral measurement resolution of charged particle systems is typically limited by the sampling raster of individual image points or dwell times per pixel on the sample, and the charged particle beam diameter. The sampling raster resolution can be set within the imaging system and can be adapted to the charged particle beam diameter on the sample. A typical raster resolution is 2 nm or below, but the raster resolution limit can be potentially reduced with no physical limitation. The charged particle beam diameter has a limited dimension, which depends on the charged particle beam operation conditions and lens. The beam resolution is limited by approximately half of the beam diameter. The resolution can be below 2 nm, for example even below 1 nm.

A common way to generate 3D tomographic data from semiconductor samples on a nanometer scale is the so-called slice and image approach elaborated for example by a dual beam system. Dual beam systems with a charged particle beam column for imaging and a FIB column for milling are operated at the so-called coincidence point, i.e. the charged particle beam optical axis, the FIB optical axis and the sample surface meet (coincide) in a single point. This can help guarantee that imaging is done at the sample point which is affected by the milling.

A slice and image approach is described for example in WO 2020/244795 A1. According to the method of WO 2020/244795 A1, a 3D volume inspection is obtained at an inspection sample extracted from a semiconductor wafer. This method involves destroying a wafer to obtain an inspection sample of block shape. On the other hand, the method can allow for a comparatively small working distance between a charged particle imaging device such as a scanning electron microscope (SEM) and more precisely its column and a sample or wafer to be imaged, for example if the two columns are arranged perpendicular to one another with the optical axis of the SEM being arranged perpendicular to the sample surface. In general, the resolution of a particle imaging device increases as the working distance decreases.

An alternative way to generate 3D tomographic data from semiconductor samples on the nanometer scale is described in WO 2021/180600 A1. According to this document, destroying the wafer is avoided by using another geometric arrangement of a milling or FIB column on the one hand and a charged particle imaging column on the other hand. By that arrangement the coincidence point can be navigated over the full wafer without the need to break the wafer. The so-called wedge-cut approach utilizes the slice and image method under a slanted angle into the surface of a semiconductor wafer. However, because of geometric constraints of an arrangement of the two columns with respect to one another, the working distance of the charged particle imaging column to a sample or wafer to be imaged is increased compared to the approach described in WO 2020/244795 A1. This can result in a good, but nevertheless relatively decreased imaging resolution.

DE 10 2013 102 776 A1 discloses a cross-section processing and observation method for determining a cutting width applying a dual beam system. The system uses a geometry different from the wedge-cut approach. A FIB column is arranged orthogonal to a sample surface and a SEM column is arranged at a slant angle to the sample surface.

WO 2021/180600 A1 discloses a method of cross-section imaging of an inspection volume in a wafer. In more detail, it discloses a dual beam device and a three-dimensional circuit pattern inspection technique by cross sectioning inspection volumes with large depth extension exceeding 1 micrometer (μm) below the surface of a semiconductor wafer. WO 2021/180600 A1 discloses a method, computer program product and apparatus for generating 3D volume image data of a deep inspection volume inside a wafer without removal of a sample from the wafer. A wedge cut approach is applied. WO 2021/180600 A1 further relates to a 3D volume image generation and a cross section image alignment method utilizing a dual beam device for three-dimensional circuit pattern inspection.

DE 10 2013 102 535 A1 discloses a dual beam device, wherein a FIB column and an SEM column are arranged orthogonal to one another. The sample to be sliced and imaged is arranged on a special holder allowing an edge cut of the sample.

### SUMMARY

The present disclosure seeks to overcome certain known limitations of the prior art.

The present disclosure also seeks to provide an improved slice and image method and a correspondingly adapted dual beam system that allow for a better imaging resolution, for example even in the presence of geometric constraints with respect to the arrangement of the columns of the dual beam device, for example when the geometry of a wedge-cut approach is applied.

The present disclosure seeks to provide improved flexibility of a workflow.

Furthermore, the present disclosure seeks to provide a fast workflow.

According to a first aspect, the disclosure provides a method for obtaining a sequence of cross-section images of a measurement site of a wafer parallel to one another. The method can also be used for imaging other types of samples; however, its value is apparent when applied for wafers without the necessity to overall destroy or break the wafer, but with the possibility to enhance the imaging resolution compared to a “normal” wedge-cut FIB/SEM arrangement. The method comprises the following steps 1a) to 1e):
1a) providing a focused ion beam (FIB) column and a charged particle beam (CPB) imaging column in a coincidence arrangement, in this coincidence arrangement a FIB optical axis of the FIB column and a CPB optical axis of the CPB imaging column coinciding at a wafer surface and forming an arrangement angle GFE between the FIB optical axis and the CPB optical axis.
1b) in the coincidence arrangement removing a cross section surface layer of measurement site of a wafer using the FIB column to make a new cross section accessible for imaging;
1c) reducing a working distance between the CPB imaging columns and the wafer surface in a direction along the axis of the CPB imaging column;
1d) imaging the new cross section at the measurement site of the wafer with the

CPB imaging column at the reduced working distance and thus not in the coincidence arrangement;
1e) increasing the working distance between the CPB imaging device and the wafer surface in the direction along the axis of the CPB imaging device until the coincidence arrangement is reached (again).

The CPB imaging device can generally be of any kind. It can be for example a scanning electron microscope (SEM) or a helium ion microscope (HIM).

The method can generally apply an arrangement as known from the wedge-cut approach. However, the disclosure implements some differences in the workflow compared to certain known workflows in the wedge-cut arrangement. General considerations of the inventors include the following. The arrangement angle GFE between the FIB column and the CPB imaging column cannot be chosen fully freely. Usually, as working distances decrease, the GFE increases, but the size of the angle GFE is limited by the available space in the system. For smaller working distances, the FIB column can start blocking the CPB imaging column.

Instead of working in the coincidence arrangement during the entire workflow as know from the art, the inventors have realized that temporarily giving up the coincidence arrangement can overall be desirable. According to the disclosure, the milling process is still carried out in the coincidence arrangement, but with an even smaller angle GFE leading to a decreased imaging resolution when supervising the milling (though the CPB imaging beam is focused onto the wafer surface, of course). However, the reduced imaging resolution is still good enough for supervising the milling. Then, for the imaging process as such, the coincidence arrangement is given up (while keeping the angle GFE as such) and the working distance of the CPB imaging column can be reduced. Imaging as such is thus carried out in a comparatively short working distance which allows to achieve a better imaging resolution (with another focused setting of the CPB imaging column). The enhanced imaging resolution can overcompensate the use of a lower imaging resolution during the milling process.

The working distance is reduced by a relative movement between the CIP imaging column and the wafer surface along the axis of the CPB imaging column. Since the working distance is reduced along the axis of the CPB imaging column, for example by a vertical stage movement, the coincidence point of the arrangement is only temporarily given up and can be re-found again later comparatively easy. Furthermore, if a high-precision stage is applied, any misalignment of the stage in the vertical direction resulting from a stage move in z-direction can be small compared to a change of typical dimensions in z-direction inside the wafer that shall be analyzed. Optionally, an additional alignment step can be included in the method. Alternatively, the relative movement between the CPB imaging column and the wafer surface could be achieved by a movement of the CPB imaging column, but this would involve moving the FIB column as well and prior to the movement of the CPB imaging column in order to “unblock” the CPB imaging column.

According to an example, the sequence of method steps 1b), 1c) 1d) and 1e) is carried out repeatedly. It can be carried out twice, three times, 10 times, 100 times or 500 times, for example.

According to an example, the method further comprises, in the coincidence arrangement, imaging the removal of the cross-section surface layer with the CPB imaging device. This imaging can supervise the milling process and can make sure that the milling is started/stopped at the correct positions.

According to an embodiment, reducing the working distance between the CPB imaging device and the wafer surface comprises moving a stage carrying the semiconductor sample, in particular vertically moving the stage. A stage move in z-direction (vertical direction) can be carried out with comparatively high precision. Furthermore, such a stage move is comparatively fast compared to the entire imaging time (for example one second (s) for a stage move compared to 20 s to 30 s imaging time). It does therefore not significantly slow-down the entire process. The size of a stage move in z-direction can be for example about 2 to 3 millimeters (mm), thus, if a working distance is for example about 5 to 6 mm, the stage move can allow to reduce the working distance approximately to half the original working distance in the coincidence arrangement. This can help enhance imaging resolution for more than one order of magnitude, for example.

According to an example, the CPB optical axis is aligned with the normal of the wafer surface. This can help facilitate operations.

According to an example, the FIB optical axis is arranged at a slant angle with respect to the wafer surface (which is the wafer top surface).

According to an example, the arrangement angle GFE is equal to or less than 45°, such as equal to or less than 40°, for example equal to or less than 35°. Optionally, the angle GFE is not smaller than 30°, since imaging of a highly slanted surface with the CPB imaging can cause problems.

According to an example, reducing the working distance between the CPB imaging column comprises moving the PCB imaging column along the PCB optical axis. Here, it is possible that the stage stays locally fixed.

The disclosure provides a computer program product with a program code adapted for executing the method as described above in various examples. The program code can be segmented or divided into a plurality of parts or modules. In general, any computer language can be applied as programming language.

The disclosure provides a one-chamber system, comprising:
a focused ion beam (FIB) column and a charged particle beam (CPB) imaging column adapted to be provided in a coincidence arrangement, in this coincidence arrangement a FIB optical axis of the FIB column and a CPB optical axis of the CPB imaging column coinciding at a wafer surface and forming an arrangement angle GFE between the FIB optical axis and the CPB optical axis, wherein the CPB optical axis is arranged in a direction perpendicular to the wafer surface;
a stage adapted for carrying a wafer and configured to be movable in a direction perpendicular to the wafer surface; and
a control;
wherein the control is configured for controlling the FIB column, the CPB imaging column and the stage for carrying out the method as described above in various examples.

The stage can directly or indirectly carry the wafer or sample. In an example, a chuck is placed on the stage itself and the wafer is placed on the chuck. The chuck can be used to arrange the wafer in a flat way for example by electrostatic attraction. It is possible that the stage is not only movable in a direction perpendicular to the wafer surface (normally defined as z-direction), but that it can be moved in other directions as well and/or that it can be rotated.

It is possible to use other systems as well to carry out the method as described above in various examples.

According to a second aspect, the disclosure provides a method for obtaining a sequence of cross-section images of a measurement site of a wafer parallel to one another, wherein the wafer is carried by a stage, the method comprising the following steps:
2a) providing a focused ion beam (FIB) column and a charged particle beam (CPB) imaging column in an offset arrangement, wherein in this offset arrangement the FIB column optical axis and the CPB optical axis intersect a wafer surface at two different positions, the difference between the two different positions defining an offset on the wafer surface, this offset allowing independently setting of working distances of the FIB column and of the CPB imaging column without geometric constraints due to the shapes and/or positions of the FIB column and the CPB imaging column;
2b) removing a cross section surface layer at a first measurement site of the wafer using the FIB column to make a new cross section accessible for imaging;
2c) moving the wafer surface by a stage movement relative to the FIB column and the CPB imaging column according to the offset;
2d) imaging the new cross section of the first measurement site of the wafer with the CPB imaging column.

According to the second aspect of the disclosure, the concept of the coincidence point is given up and instead an offset arrangement is used. The advantage is that working distances of the FIB columns and of the CPB imaging columns can be set independently from one another and can thus be optimized. For example, a short working distance of the CPB imaging column is not hindered by the FIB column. Therefore, an imaging resolution can be improved compared to a “normal” wedge-cut arrangement with coincidence point. The additional stage moves can also be comparatively fast. It is generally desirable to use a high-precision stage. Optionally, one or more registration or alignment steps can be implemented. Also according to the second aspect of the disclosure, there is no necessity to overall destroy or break a wafer. In an example, as in the “normal” wedge cut approach, the method can be carried out with an arrangement, according to which the FIB optical axis is arranged at a slant angle with respect to a top wafer surface.

According to an example, the method further comprises 2e) moving the wafer surface by a stage movement relative to the FIB column and the CPB imaging column according to the offset.

In general, step 2e) can be realized in two different ways. According to an example, step 2e) inverts step 2c), so a measurement site is milled at a first position, transferred to a second position for imaging and transferred back to the first position for further milling. Here, overall, only two different columns are applied. However, according to an alternative approach, more than two columns can be applied which can be arranged in a line alternatingly, for example, each offset from one another by the same value. Then, processing can be carried out in a processing line. Each offset advances the measurement site from one column to the next column.

According to an example, the sequence of method steps 2b), 2c), 2d) and 2e) is carried out repeatedly.

According to an example, the relative movement comprises a lateral stage movement or a stage rotation. The stage rotation allows for a comparatively well-defined and fast switch between two positions, in one of the positions milling takes place and in the other position imaging takes place. The lateral movement can be used for example in a processing line implementation.

According to an example, a working distance of the FIB column is optimized and/or a working distance of the CPB imaging column is optimized.

According to an example, the offset matches a distance between the first measurement site on the wafer surface and a second measurement site on the wafer surface.

According to an example, the method further comprises obtaining a sequence of cross-section images of the second measurement site of a wafer parallel to one another by repeatedly carrying out the sequence of method steps 2b), 2c) and 2d) at the second measurement site, wherein the step of removing a cross section surface layer at the second measurement site of the wafer is carried out simultaneously with imaging the new cross section of the first measurement site of the wafer with the CPB imaging column and wherein the step of removing a cross section surface layer at the first measurement site of the wafer is carried out simultaneously with imaging the new cross section of the second measurement site of the wafer with the CPB imaging column.

This example can allow for parallelizing the entire process which leads to an overall speed-up. The method steps of milling (removing a cross-section image layer) and imaging are carried out at least partly simultaneously. The processing steps timewise at least partly overlap. It is for example possible that milling and imaging processing steps start at the same point in time, but that one process is ended earlier (faster) than the other. A common starting point is advantageous for synchronization of the processes. Other realizations are also possible.

According to another aspect, the disclosure is directed to a computer program product with a program code adapted for executing the method as described above in various example.

According to another aspect of the disclosure, the disclosure provides a one-chamber system, comprising:
a focused ion beam (FIB) column and a charged particle beam (CPB) imaging column adapted to be arranged in an offset arrangement, wherein in this offset arrangement the FIB optical axis and the CPB optical axis intersect a wafer surface at two different positions, the difference between the two different positions defining an offset on the wafer surface, this offset having a size big enough for allowing an independent setting of working distances of the FIB column and of the CPB imaging column without geometric constraints due to the shapes and/or positions of the FIB column and the CPB imaging column;
a stage adapted for carrying a wafer and configured to be movable within a plane parallel to the wafer surface; and
a control;
wherein the control is configured for controlling the FIB device, the CPB imaging device and the stage for carrying out the method as described above in various examples of the second aspect of the disclosure.

The stage is movable within a plane parallel to the wafer surface. Therefore, the stage can for example be rotated around an axis perpendicular to the wafer surface. Additionally or alternatively, the stage can be configured for lateral movements for example in x-direction and/or y-directions. It is also possible that the stage is additionally vertically movable (in z-direction).

It is possible to use other systems as well to carry out the method as described above in various examples of the second aspect of the disclosure.

According to a third aspect, the disclosure provides a method for obtaining a sequence of cross-section images of a measurement site of a wafer parallel to one another, comprising the following steps:
3a) providing a focused ion beam (FIB) column and a charged particle beam (CPB) imaging column in a coincidence arrangement, in this coincidence arrangement a FIB optical axis of the FIB column and a CPB optical axis of the CPB imaging column coinciding at a wafer surface and forming an arrangement angle GFE between the FIB optical axis and the CPB optical axis;
3b) determining either an optimized working distance for the FIB column and a tradeoff working distance for the CPB imaging column or determining a tradeoff working distance for the FIB column and an optimized working distance for the CPB imaging column;
3c) moving the FIB column along its optical axis to arrange the FIB column in its determined working distance (which is either optimized or tradeoff) and/or moving the CPB imaging column along its optical axis to arrange the CPB imaging column in its determined working distance (which is either tradeoff or optimized);
3d) removing a cross section surface layer at the measurement site of the wafer using the FIB column arranged in its working distance to make a new cross section accessible for imaging; and
3e) imaging the new cross section at the measurement site of the wafer with the CPB imaging column arranged in its working distance.

According to such embodiments, it is decided which of the aspects “milling” or “imaging” is of higher importance in a concrete step. The more important aspect can then be given the higher weight or priority by optimizing the respectively assigned working distance of one of the columns. The other working distance termed “tradeoff” working distance is not optimum, but still good and/or chosen according to the best remaining possibility. For example, if in a use case in which the imaging resolution is of higher importance than the milling quality, the working distance of the CPB imaging column can be reduced at the price of decreasing the working distance of the FIB column. An algorithm for determining the tradeoff working distances can be applied. Also according to this third aspect of the disclosure, there is no necessity to overall destroy or break a wafer. In an example, as in the “normal” wedge cut approach, the method can be carried out with an arrangement according to which the FIB optical axis is arranged at a slant angle with respect to a top wafer surface.

According to an example, the sequence of method steps 3d) and 3e) are carried out repeatedly.

According to an example, step 3c) comprises:
decreasing the working distance of the FIB column and increasing the working distance of the CPB imaging column, or
increasing the working distance of the FIB column and decreasing the working distance of the CPB imaging column.

According to an aspect, the disclosure provides a computer program product with a program code adapted for executing the method as described above in various embodiments according to the third aspect of the disclosure.

According to an aspect, the disclosure provides a one-chamber system, comprising:
a focused ion beam (FIB) column and a charged particle beam (CPB) imaging column adapted to be arranged in a coincidence arrangement, in this coincidence arrangement a FIB optical axis of the FIB column and a CPB optical axis of the CPB imaging column coinciding at a wafer surface and forming an arrangement angle GFE between the FIB optical axis and the CPB optical axis,
wherein the FIB column is configured to be movable along its FIB optical axis and wherein the CPB imaging column is configured to be movable along its CPB optical axis;
a stage adapted for carrying a wafer; and
a control;

wherein the control is configured for controlling the FIB column, the CPB imaging column and the stage for carrying out the method as described above in various examples with respect to the third aspect of the disclosure.

It is possible to use other systems as well to carry out the method as described above in various examples of the third aspect of the disclosure.

According to a fourth aspect, the disclosure provides a method for obtaining a sequence of first cross-section images of a first measurement site situated on a first wafer and for obtaining a sequence of second cross-section images of a second measurement site situated on a second wafer, comprising:
4a) Providing a first wafer on a first stage and registering the first wafer on the first stage;
4b) Providing a second wafer on a second stage and registering the second wafer on the second stage;
4c) Removing a first cross section surface layer of the first measurement site of the first wafer using the FIB column working at a set FIB working distance to make a first new cross section accessible for imaging;
4d) Exchanging the positions of the first stage and the second stage;
4e) Imaging the first new cross section at the first measurement site of the first wafer with the CPB imaging column at a set working distance and simultaneously removing a second cross section surface layer of the second measurement site of the second wafer using the FIB column at the set FIB working distance to make a second new cross section accessible for imaging;
4f) Exchanging the positions of the first stage and the second stage;
4g) Imaging the second new cross section at the second measurement site of the second wafer with the CPB imaging column at the set working distance and simultaneously removing another first cross section surface layer of the first measurement site of the first wafer using the FIB column at the set FIB working distance to make another first new cross section accessible for imaging.

According to an example, the set working distance of the CPB imaging column can be an optimal working distance for the specific use case. Similarly, the set working distance of the FIB imaging column can be an optimal working distance for the specific use case. The working distances can be set independently from one another, since the columns don't block each other, but are used in combination with different stages.

Exchanging or switching the positions of the first and second stages can be realized in an analogous manner as known in the art and as described for example in U.S. Pat. No. 7,161,659 BB. Exchanging the positions of the stages leads to a parallelized and therefore faster process.

According to an example, the sequence of method steps 4d), 4e), 4f) and 4g) are carried out repeatedly. The method steps can be repeated until the measurement sites in both wafers have been milled and imaged with the desired slice thickness.

According to an embodiment, a plurality of first measurement sites on the first wafer are sequentially milled and sequentially imaged; and a plurality of second measurement sites on the second wafer are sequentially milled and sequentially imaged. Therefore, before exchanging the positions of the stages, all measurement sites present on one wafer can be either milled (one slice) or imaged, respectively. Milling and imaging is once again carried out in parallel and therefore at least partly simultaneously.

According to an example, removing the first or/and second cross section layer surface is supervised by low-resolution imaging; and/or imaging the new first or/and new second cross section comprises high-resolution imaging. The terms “high-resolution” and “low-resolution” imaging are relative terms; they should not be interpretated in an absolute sense. However, the terms indicate that one of the resolutions is better or worse than the other one. This can have an impact on the columns applied/their working distances: Since for the arrangement of the FIB column used for milling a comparatively low imaging resolution is sufficient for supervising or monitoring the milling, another CPB imaging column can be applied which can for example be arranged according to the normal wedge-cut symmetry. Still, since the milling process is the more important process in this cross-beam arrangement, the working distance of the FIB column can be optimized, the CPB imaging column working distance can be adapted to the prioritized FIB column working distance setting. In contrast thereto, for the imaging process as the real image generating process the optimum working distance can be set for imaging measurement sites located on a wafer of the stage actually present at the position of the CPB imaging column.

According to an example, low-resolution imaging is carried with a low-resolution scanning electron microscope (SEM) arranged in a cross-beam arrangement with the FIB column used for removing the first and second cross section surface layers; and/or high-resolution imaging is carried out with a high-resolution scanning electron microscope (SEM), a helium ion microscope (HIM) or a multibeam scanning electron microscope (MultiSEM). The high-resolution scanning electron microscope can for example be a corrected scanning electron microscope comprising an additional electrostatic lens for correcting imaging aberrations.

According to an example, exchanging the positions of the first stage and the second stage comprises transferring registration information. Therefore, it is not necessary to register the wafer on the respective stage for each column separately, but in general one registration may be sufficient. Optionally, a further alignment step can be implanted to correct minor positional deviations.

According to an example, the FIB column is arranged in a first chamber and wherein the CPB imaging column is arranged in a second chamber. This has the advantage that mill redeposition does not disturb the imaging quality of the (high-resolution) CPB imaging column.

According to an example, exchanging the position of the first and second stage comprises transferring one of the stages from the first chamber to the second chamber and vice versa. The transfer can be realized via one or two vacuum locks.

According to an aspect, the disclosure provides a computer program product with a program code adapted for executing the method as described above with respect to various example of according to fourth aspect of the disclosure.

According to an aspect, the disclosure provides a dual chamber system, comprising:
a first chamber with a focused ion beam (FIB) column and a low resolution charged particle beam (CPB) imaging column adapted to be arranged in a wedge-cut coincidence arrangement, in this coincidence arrangement a FIB optical axis of the FIB column and a CPB optical axis of the low resolution CPB imaging column coinciding at a wafer surface and forming an arrangement angle GFE between the FIB optical axis and the CPB optical axis;
a second chamber with a high-resolution CPB imaging column, its optical axis being arranged perpendicular to a wafer surface;
a first stage for carrying a first wafer;
a second stage for carrying a second wafer;
a stage exchange mechanism configured for exchanging the positions of the first stage and the second stage; and
a control,
wherein the control is configured for controlling the first chamber with the FIB column and the low resolution CPB imaging column, the second chamber with the high-resolution CPB imaging column, the first stage, the second stage and the stage exchange mechanism for carrying out the method as described above in various examples of the fourth aspect of the disclosure.

It is possible to use other systems as well to carry out the method as described above in various examples of the fourth aspect of the disclosure.

According to a fifth aspect, the disclosure provides a method for obtaining at least one sequence of parallel cross-section images of at least one measurement site of a wafer, comprising the following steps:
5a) providing a first focused ion beam (FIB) column and a first charged particle beam (CPB) imaging column in a wedge-cut coincidence arrangement in a first chamber, in this coincidence arrangement a FIB optical axis of the FIB column and a CPB optical axis of the CPB imaging column coinciding at a wafer surface and forming an arrangement angle GFE between the FIB optical axis and the CPB optical axis;
5b) providing a second FIB column and a second CPB imaging column in an edge-cut coincidence arrangement in a second chamber, in this edge-cut coincidence arrangement a FIB optical axis of the second FIB column and a CPB optical axis of the second CPB imaging column coinciding at a wafer or sample surface and being perpendicular to one another, the optical axis of the second CPB column being arranged perpendicular to the wafer or sample surface and the CPB column being arranged at a short working distance allowing for high-resolution imaging;
5c) registering the first wafer with at least one measurement site on a first stage;
5d) milling around the at least one measurement site with first FIB column in the first chamber, thus generating at least one chunk, and supervising the milling with the first CPB imaging column in the first chamber;
5e) lifting-out the at least one chunk from the wafer and arranging the at least one chunk on a sample holder in such a way that a measurement site of each chunk is placed at an edge of the sample holder;
5f) transferring the sample holder with the at least one chunk into the second chamber;
5g) registering the at least one measurement site included in the at least one chunk on the second stage;
5h) obtaining at least one sequence of parallel cross-section images of the at least one measurement site by repeatedly milling the at least one chunk with the second FIB column and repeatedly imaging the at least one chunk with the second CPB column in the second chamber.

With this lift-out procedure and adequate positioning of the chunk on a sample holder (at an edge) it is possible to guarantee that regions of interest or measurements sites are situated close to an edge of the sample holder. Thus, an arrangement of the PCB imaging column perpendicular to the wafer surface or the surface of the chunk es enabled which leads in turn to a shorter possible working distance and an enhanced imaging resolution.

According to an example, the method comprises:
5i) moving the second stage to make a second measurement site accessible for milling and imaging. The second measurement site is normally included in a second chunk. This second chunk is also positioned at an edge of the sample holder. Moving the second stage can be realized in different ways and the movement can depend on the geometric characteristic of the second stage. If the second stage is round (its surface is a circle), the movement can be a rotation. If the second stage is of bank shape (realized for example by a belt), the movement can be a lateral movement. Overall, a linear arrangement of chunks can thus be achieved on the bank, all chunks being positioned at an edge.

According to an example, the method further comprises providing a plurality of sample holders and sequentially handling the plurality of sample holders in the first chamber and in the second chamber according to steps 5d) to 5h). It is therefore possible to extract more chunks from one wafer than can be placed on one sample holder. Of course, the entire procedure can be repeated for a second or further wafer.

According to a further aspect, the disclosure provides a computer program product with a program code adapted for executing the method as described above in various examples of the fifth aspect.

According to a further aspect, the disclosure provides a dual chamber system, comprising:
a first chamber, comprising
   a first focused ion beam (FIB) column and a first charged particle beam (CPB) imaging column adapted to be arranged in a wedge-cut coincidence arrangement, in this wedge-cut coincidence arrangement a FIB optical axis of the FIB column and a CPB optical axis of the low resolution CPB imaging column coinciding at a wafer surface and forming an arrangement angle GFE between the FIB optical axis and the CPB optical axis;
   a first stage for carrying a wafer;
   a sample holder adapted for carrying at least one chunk,
   a manipulator configured for lifting-out chunks milled from the wafer and configured for placing the chunks on the sample holder;
a second chamber, comprising
   a second FIB column and a second CPB imaging column in an edge-cut coincidence arrangement, in this edge-cut coincidence arrangement a FIB optical axis of the second FIB column and a CPB optical axis of the second CPB imaging column coinciding at a wafer or sample surface and being perpendicular to one another, the optical axis of the second CPB column being arranged perpendicular to the wafer or sample surface and the second CPB column being arranged at a short working distance allowing for high-resolution imaging;
   a second stage adapted for carrying the sample holder;
a sample holder transfer mechanism configured for transferring the sample holder from the first chamber to the second chamber and for placing the sample holder on the second stage; and
a control,
wherein the control is configured for the first chamber with the first FIB column, the first CPB imaging column, the first stage, the sample holder and the manipulator, the second chamber with the second chamber with the second FIB column, the second CPB imaging column and the second stage, and the sample holder transfer mechanism for carrying out the method as described above with respect to the fifth aspect of the disclosure.

This example allows for efficient batch processing.

It is possible to use other systems as well to carry out the method as described above in various examples of the fifth aspect of the disclosure.

The embodiments or examples as described above can be fully or partly combined with one another as long as no technical contradictions occur. This also holds for examples or embodiments describing different aspects or aspects of the disclosure.

### BRIEF DESCRIPTION OF THE DRAWINGS

The present disclosure will be even more fully understood with reference to the following drawings, in which:

FIG. 1 is an illustration of the cross-section imaging technique explained at a sample extracted from a wafer;

FIG. 2 is an illustration of a dual beam apparatus configured for the cross-section imaging technique in wedge-cut geometry, applied to a wafer;

FIG. 3 shows details of the cross-section imaging technique in wedge-cut geometry;

FIG. 4 illustrates a slanted cross-section image slice through a plurality of HAR structures;

FIG. 5 illustrates a first workflow according to the disclosure;

FIG. 6A-6B schematically illustrate a system for carrying out the first workflow;

FIG. 7 illustrates a second workflow according to the disclosure;

FIGS. 8A-8B schematically illustrate a system for carrying out the second workflow;

FIG. 9 illustrates a third workflow according to the disclosure;

FIG. 10 illustrates a fourth workflow according the disclosure;

FIG. 11 schematically illustrates a dual chamber system for carrying out the fourth workflow;

FIG. 12 illustrates a fifth workflow according to the disclosure;

FIG. 13 schematically illustrates a dual chamber system for carrying out the fifth workflow; and

FIGS. 14A-14B schematically illustrate the geometrical characteristics and constraints in a dual beam system according to the state of the art and according to an aspect of the disclosure.

### DETAILED DESCRIPTION

Same reference signs in the figures indicate same features, even if not further described in the text.

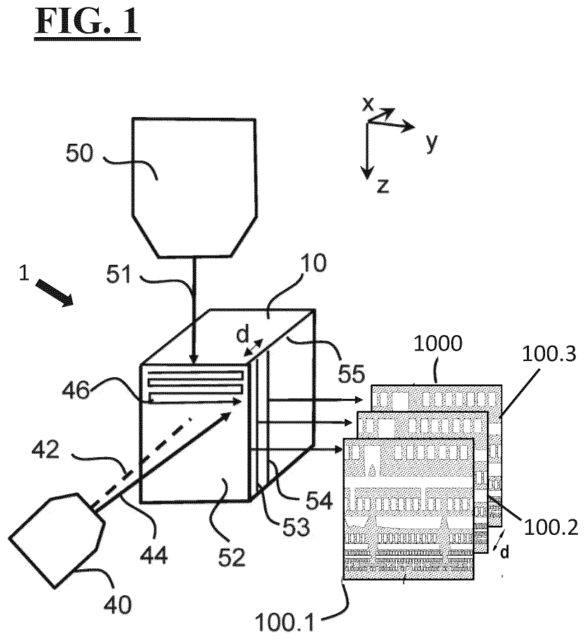

FIG. 1 shows a schematic view of the common cross-section image approach to obtain a 3D volume image of an integrated semiconductor sample. With the cross-section approach, also called slice and image approach, three-dimensional (3D) volume image acquisition is achieved by a “step and repeat” fashion. First, the integrated semiconductor sample is prepared for the common cross-section image approach by methods known in the art. A small block or chunk is extracted from a wafer that is then further analyzed. Throughout the disclosure, “cross-section image” and “slice” will be used as synonyms.

In a step, a thin surface layer or “slice” of material is removed. This slice of material may be removed in several ways known in the art, including the use of a focused ion beam milling or polishing at glancing angle by focused ion beam (FIB) column 50. For example, the focused ion beam 51 propagates almost parallel to z-axis and is scanned in y-direction to mill through the top surface 55 of the sample 10 (which can for example be a part of a wafer) and expose a new cross-section surface 52 in an y-z-plane. As a result, the new exposed cross-section surface 52 is accessible for imaging. In a subsequent step, the cross-section surface layer 52 is raster scanned by a charged particle beam (CPB) imaging system 40, such as a scanning electron microscope (SEM) or a second FIB, to obtain a cross-section image slice 100.1. The optical axis 42 of the charged particle imaging system 40 can be arranged to be parallel to the x-direction or inclined at an angle to the x-direction. Secondary as well as backscattered electrons are collected by a detector (not shown) to reveal a material contrast inside of the integrated semiconductor sample, and are visible in the cross-section image slice 100.1 as different grey levels. Metal structures generate brighter measurement results. The surface layer removal by milling and the cross-section imaging process are repeated through cross-section surfaces 53 and 54 and further cross-section surfaces at equal distance d, and a sequence of 2D cross-section image slices 1000, comprising for example N cross-section image slices 100.2, 100.3, . . . 100.N in different depths is obtained so as to build up a three dimensional 3D dataset. The representative cross-section image slice 100.1 is obtained by measurement of a commercial Intel processor integrated semiconductor chip with 14 nm technology.

With the method, at least first and second cross-section image slices are generated by subsequently milling cross-section surfaces into the integrated semiconductor sample with a focused ion beam to expose or to make accessible a sequence of cross-section surface for imaging and imaging each cross-section surface of the integrated semiconductor sample with a charged particle beam imaging system 40. From the sequence of N 2D cross-section image slices 1000, a 3D image of the integrated semiconductor structure is reconstructed. The distance d of the cross-section image slices 100.1, 100.2, 100.3 can be controlled by the FIB milling or polishing process and can be between 1 nm and 30 nm.

In the above example, the cross-section image planes are oriented perpendicular to the top surface 55 of the integrated semiconductor wafer, with the normal to the wafer top surface 55 oriented parallel to the z-direction, as shown in FIG. 1. This results in 2D cross-section image slices which are oriented parallel to the y-z plane, or, in other words, the cross-section image planes include the z-axis or wafer normal axis, and the imaging direction x is parallel to the wafer surface. The conventional slice and image method in this conventional geometry is therefore only applicable to samples which are extracted from a wafer.

It is of course also possible to exchange the positions of the FIB column 50 and of the CPB imaging column 40. Then, the CPB optical axis can be oriented perpendicular to the top surface 55 of the sample 10. This arrangement can be used for imaging HAR structures extending into the depth of the sample 10.

In both arrangements described above, a working distance of the FIB columns and of the CPB imaging columns can be set individually. It is therefore possible to optimize both working distances. In general, the shorter the working distance is, the better the imaging resolution becomes. Therefore, since a short working distance can be set without geometric constraints, high-resolution imaging with the CPB imaging columns 40 is possible.

However, a general issue stays the same: A measurement site of a wafer is to be situated close to an edge of the wafer to allow for a measurement with the depicted geometric arrangement of the columns 40, 50. Otherwise, the wafer has to be destroyed and a sample 10 or chunk has to be extracted from the wafer to artificially create an edge and thus a situation suited for further analysis.

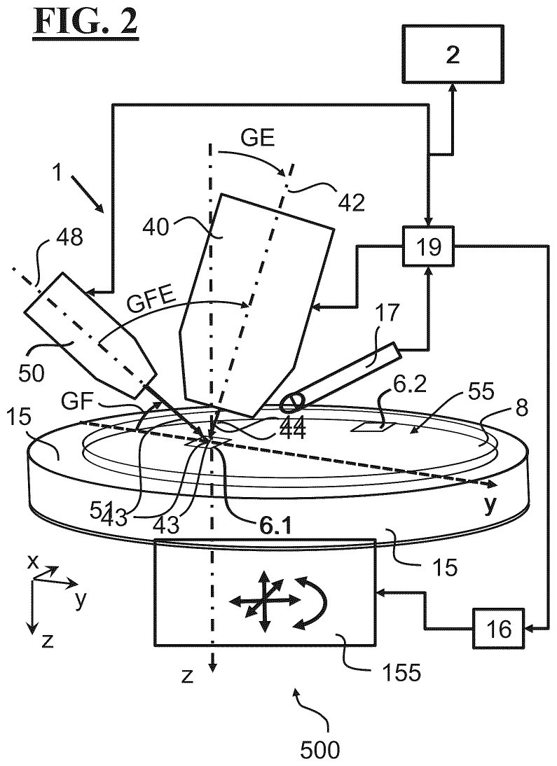

FIG. 2 discloses a method of a 3D volume image generation utilizing the slice and image method applied to an inspection volume inside a wafer in the so called “wedge-cut” approach or wedge-cut geometry, without removing a sample 10 from the wafer 8. The slice and image method is applied to an inspection volume with dimensions of few μm, for example 5 μm to 10 μm lateral extension in 200 mm or 300 mm wafers, without removal of samples from the wafer 8. A groove or edge is milled in the top surface 55 of an integrated semiconductor wafer 8 to make accessible a cross-section surface at an angle to the top surface 55. 3D volume images of inspection volumes are acquired at a limited number of measurement sites, for example representative sites of dies, for example at process control monitors (PCM), or at sites identified by other inspection tools. The slice and image method will destroy the wafer only locally, and other dies may still be used, or the wafer may still be used for further processing.

FIG. 2 discloses the wafer inspection system 500 configured for a slice and imaging method under wedge cut geometry with a dual beam device 1. For a wafer 8, several measurement sites, comprising measurement sites 6.1 and 6.2, are defined in a location map or inspection list generated from an inspection tool or from design information. The wafer 8 is placed on a wafer support table 15. The wafer support table 15 is mounted on a stage 155 with actuators and position control. Actuators and mechanisms for precision control for a wafer stage such as laser interferometers are known in the art. A control unit 16 configured to control the wafer stage 155 and to adjust a measurement site 6.1 of the wafer 8 at the intersection point 43 of the dual-beam device 1. The dual beam device 1 comprises a FIB column 50 with a FIB optical axis 48 and a charged particle beam (CPB) imaging system 40 with optical axis 42. At the intersection point 43 of both optical axes of FIB and CPB imaging system, the wafer surface 55 is arranged at a slant angle GF to the FIB axis 48. FIB axis 48 and CPB imaging system axis 42 include an angle GFE, and the CPB imaging optical axis 42 forms an angle GE with normal to the wafer surface 55. In the coordinate system of FIG. 1, the normal to the wafer surface 55 is given by the z-axis. The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF. In the example of FIG. 2, the slant angle GF is approximately 30°. The actual slant angle of the slanted cross-section surface can deviate from the slant angle GF by up to 1° to 4° due to the beam divergency of the focused ion beam, for example a Gallium-Ion beam. With the charged particle beam imaging system 40, inclined under angle GE to the wafer normal, images of the milled surfaces are acquired. In the example of FIG. 2, the angle GE is about 15°. However, other arrangements are possible as well, for example with GE=GF, such that the CPB imaging system axis 42 is perpendicular to the FIB axis 48, or GE=0°, such that the CPB imaging system axis 42 is perpendicular to the wafer surface 55.

During imaging, a beam of charged particles 44 is scanned by a scanning unit of the charged particle beam imaging system 40 along a scan path over a cross-section surface of the wafer 8 at measurement site 6.1, and secondary particles as well as scattered particles are generated. Particle detector 17 collects at least some of the secondary particles and scattered particles and communicates the particle count with a control unit 19. Other detectors for other kinds of interaction products may be present as well. Control unit 19 is in control of the charged particle beam imaging column 40, of FIB column 50 and connected to a control unit 16 to control the position of the wafer 8 mounted on the wafer support table 15 via the wafer stage 155. Control unit 19 communicates with operation control unit 2, which triggers placement and alignment for example of measurement site 6.1 of the wafer 8 at the intersection point 43 via wafer stage movement and triggers repeatedly operations of FIB milling, image acquisition and stage movements.

Each new intersection surface is milled by the FIB beam 51, and imaged by the charged particle imaging beam 44, which is for example scanning electron beam or a Helium-Ion-beam of a Helium ion microscope (HIM).

However, since the FIB column 50 and the CPB imaging column 40 are both positioned above the wafer top surface 55, there exist geometric constraints for their arrangement. It is no longer possible to individually optimize both working distances, since the columns 40, 50 start blocking at each other at short working distances. As a general practical rule, the position of the FIB column 50 limits and thus “defines” the working distance of the CPB imaging column 40. The working distance of the CPB imaging column 40 can normally not be made shorter than 4 to 5 mm. In contrast thereto, a working distance of the CPB imaging column 40 as depicted in FIG. 1 can me made as short as about 2 mm. Therefore, in the wedge-cut arrangement depicted in FIG. 2, the imaging resolution is typically reduced by an order of magnitude compared to the edge-arrangement depicted in FIG. 1.

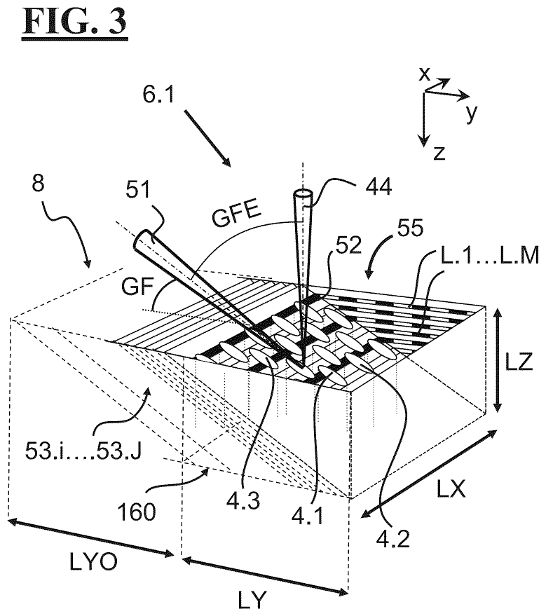

FIG. 3 illustrates further details of the slice and imaging method in the wedge cut geometry. By repetition of the slicing and imaging method in wedge-cut geometry, a plurality of J cross-section image slices comprising image slices of cross-section surfaces 52, 53.i . . . 53.J is generated and a 3D volume image of an inspection volume 160 at an inspection site 6.1 of the wafer 8 at measurement site 6.1 is generated. FIG. 3 illustrates the wedge cut geometry at the example of a 3D-memory stack. The cross-section surfaces 53.1 . . . 53.N are milled with a FIB beam 51 at an angle GF of approximately 30° to the wafer surface 9, but other angles GF, for example between GF=20° and GF=60° are possible as well. FIG. 3 illustrates the situation, when the surface 52 is the new cross-section surface which was milled last by FIB 51. The cross-section surface 52 is scanned for example by SEM beam 44, which is in the example of FIG. 3 arranged at normal incidence to the wafer surface 55, and a high-resolution cross-section image slice is generated. The cross-section image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . . L.M, which comprise for example SiO2, SiN- or Tungsten lines or word-line layers. The maximum number M of layers is typically more than 50, for example more than 100 or even more than 200. The HAR-structures and layers extend throughout most of the volume in the wafer but may comprise gaps. The HAR structures typically have diameters below 100 nm, for example about 80 nm, or for example 40 nm. The cross-section image slices contain therefore first cross-section image features as intersections or cross-sections of the HAR structure footprints at different depth (Z) at the respective XY-location. In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.J is exposed and accessible for imaging with the charged particle imaging beam 44.

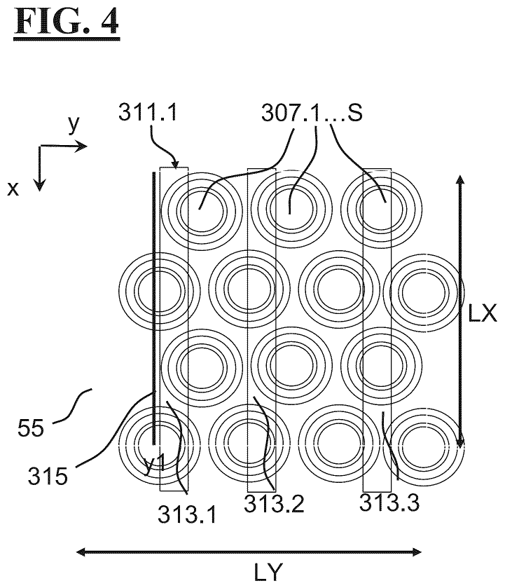

FIG. 4 illustrates a slanted cross-section image slice through a plurality of HAR structures. In more detail, FIG. 4 shows a cross-section image slice 311.1 generated by the imaging charged particle beam 41 and corresponding to the cross-section surface 301.1. The cross-section image slice 311.1 comprises an edge line 315 between the slanted cross-section and the surface 55 of the wafer at the edge coordinate y1. Right to the edge, the image slice 311.1 shows several cross-sections 307.1 . . . 307.S through the HAR structures which are intersected by the cross-section surface 301.1. In addition, the image slice 311.1 comprises cross-sections of several word lines 313.1 to 313.3 at different depths or z-positions. With these word lines 313.1 to 313.3, a depth map Z₁(x,y) of the slanted cross-section surface 301.1 can be generated.

In an example, features and 3D positions of the semiconductor structures of interest, for example the positions of the HAR channels, are detected by image processing methods, for example from HAR centroids. A 3D volume image generation including image processing methods and feature based alignment is further described in U.S. provisional application No. 62/858,470 and German patent application 102019006645.6, which are hereby fully incorporated by reference. It should be mentioned, that the layers and HAR structures do not need to extend through the whole measured volume.

For improved 3D tomography data and 3D metrology measurement problems, an improved imaging resolution is desired. At the same time, a wafer comprising the measurement sites of interest, shall be kept unbroken and therefore still usable after 3D image generation of a measurement site.

The present disclosure solves these problems by decoupling the working distance of a CPB imaging columns from FIB geometry induced constraints as already explained in the general part of the description. In the following, several examples further illustrating the disclosure shall be described. These examples shall however not be regarded as limiting the disclosure.

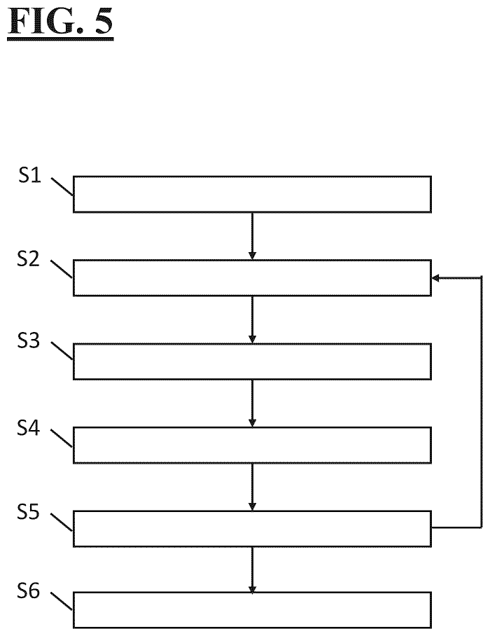

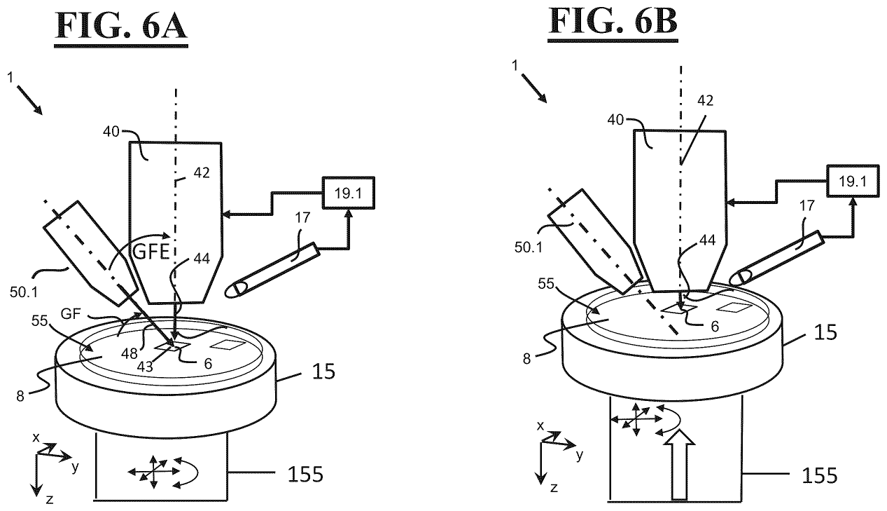

FIG. 5 illustrates a first workflow according to the disclosure and FIGS. 6A-6B schematically illustrate a dual beam device 1 suited for carrying out the first workflow. FIG. 6A in general discloses a slightly modified wedge-cut arrangement compared to the wedge-cut arrangement depicted in FIG. 2. As in FIG. 2, a wafer 8 with a plurality of measurement sites 6 (here: two measurement sites) is arranged on a wafer support table 15 which is held by a stage 155. The stage in the depicted example can be moved in all three dimensions of space (x, y, z), indicated by the arrows. Furthermore, a stage 155 rotation or at least a rotation of the wafer support table 15 is possible. The movements can be controlled by a stage control unit 16 (not shown in FIG. 6).

In the depicted example, the CPB imaging optical axis 42 is arranged perpendicular to the wafer top surface 55. This can allow for top-down imaging of HAR structures in a sample or wafer 8. The FIB column 50.1 is arranged at a slant angle with respect to the wafer top surface 55. The FIB optical axis 48 and the CPB optical axis 42 intersect each other in the coincidence point 43 which is situated at the wafer top surface 55. However, compared to the arrangement depicted in FIG. 2, the arrangement angle GFE between the FIB optical axis 48 and the CPB optical axis 42 is decreased in FIG. 6a. This would increase the working distance of the CPB imaging column if imaging would be carried out in this position. However, according to the disclosure, only a milling process with the FIB column 50.1 is carried out in the depicted coincidence arrangement. The working distance of the FIB column 50.1 can be chosen optimum in the depicted example.

After a cross section surface layer has been removed with the FIB 50.1, the FIB is stopped or blanked. Then the arrangement of the columns 50.1 and 40 is changed to the arrangement depicted in FIG. 6B: The working distance of the CPB imaging column 42 is reduced along the direction of the CPB optical axis. In the depicted case, this reduction is achieved by a movement of the stage in z-direction which is indicated by the big arrow at the stage 155. However, additionally or alternatively, a movement of the CPB imaging column 40 itself is also possible. After the reduction of the working distance, imaging is carried out at the shorter working distance. This shorter working distance allows for a better imaging resolution. Furthermore, a stage move in z-direction can be carried out rather fast and also with a rather high precision. After imaging one cross section made accessible, the stage 155 (or the CPB imaging column 40) can be moved down again back until the coincidence arrangement is reached again. Then, the next slice can be milled with the FIB 50.1 and the process can be repeated for the measurement site 6 as well as for other measurement sites.

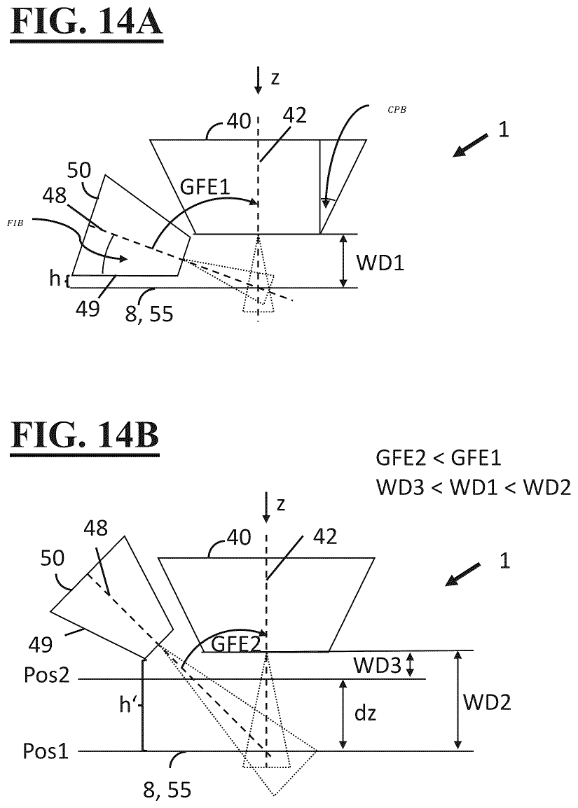

FIGS. 14A-14B further illustrate geometrical characteristics and constraints in a dual beam system 1: FIG. 14A) depicts the geometrical arrangement for a wedge-cut according to the state of the art and FIG. 14B) depicts the geometrical characteristics and advantages according to the first aspect of the present disclosure. Practically, the last lens in a sequence of lenses in a focused ion beam column 50 as well as in a charged particle beam column 40 limits the available space between the columns 50, 40 and the sample or wafer 8: The outer shape of the columns 50, 40 near the wafer 8 can be approximated by truncated cones with opening angles α_{FIB} and α_{CPB}, respectively. It is apparent that it is desirable for the FIB column 50 and the CPB imaging column 40 to not block each other, for example for the FIB column 50 to not be arranged within the available space below the CPB imaging column 40.

Furthermore, according to a dual beam device 1 arrangement according to the state of the art as shown in FIG. 14A, a bottom edge 49 of the FIB column 50 is arranged parallel to the wafer 8 and the wafer top surface 55. The distance h between the bottom edge 49 and the top wafer surface 55 is chosen small so that a working distance WD1 between the CPB imaging column 40 can be made small as well which could allow for a high resolution imaging (the smaller the working distance, the better the resolution in general). Still, in practice, there exists a minimum distance h and thus a minimum possible working distance WD1, since otherwise the FIB column 50 would contact the wafer 8. Furthermore, it has to be born in mind that normally the wafer 8 is moved within the plane perpendicular to the optical axis (here: z-axis) of the CPB imaging column 40 and it does not contact the FIB column 50 during the movement.

According to the first aspect of the present disclosure, the geometrical arrangement of the dual beam device 1 is different: As shown in FIG. 14B), the FIB column 50 is retracted from the wafer 8, the bottom edge 49 is no longer arranged parallel to the wafer top surface 55 and the arrangement angle GFE2 is smaller than the arrangement angle GFE1. So in a milling process the working distance WD2 of the CPB imaging column 40 is bigger than the working distance WD1 shown in FIG. 14A). During milling in the coincidence arrangement (corresponding to a first position Pos1 of the wafer 8 and the wafer top surface 55), the resolution of the CPB imaging column 40 is thus reduced. However, this resolution is still good enough to supervise the milling.

On the hand, after milling, it is now possible in the new arrangement according to the first aspect of disclosure to reduce the relative distance between the wafer top surface 55 and the CPB imaging column 40, for example by a stage move dz in z-direction. The second reduced position Pos2 is also indicated in FIG. 14B). In the second position Pos2, a working distance WD3 which is shorter than the working distance WD1 can be used for high resolution imaging.

FIG. 5 summarizes the exemplary workflow: In step S1 a focused ion beam (FIB) column 50.1 and a charged particle beam (CPB) imaging column 40 are provided in a coincidence arrangement. In step S2 in the coincidence arrangement a cross section surface layer of a measurement site 6 of a wafer 8 is removed using the FIB column 50.1 to make a new cross section accessible for imaging. In step S3 a working distance between the CPB imaging column 40 and the wafer top surface 55 in a direction along the optical axis 42 of the CPB imaging column 40 is reduced, for example by stage move in z-direction. In step S4 the new cross section at the measurement site 6 of the wafer 8 is imaged with the CPB imaging column 40 at the reduced working distance and thus not in the coincidence arrangement. In step S5 the working distance between the CPB imaging column 40 and the wafer top surface 55 in the direction along the axis 42 of the CPB imaging column 40 increased until the coincidence arrangement is reached (again). The steps S2 to S5 can be carried out repeatedly until a measurement site is milled and imaged completely. Then in step S6 the process ends. Of course, it is possible to repeat the workflow for the next measurement site 6.

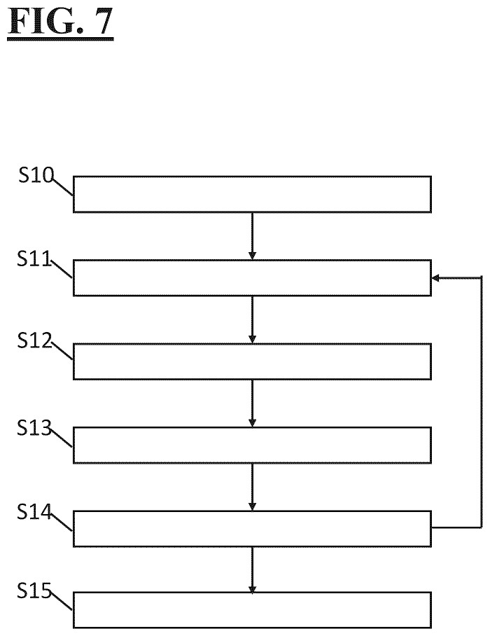

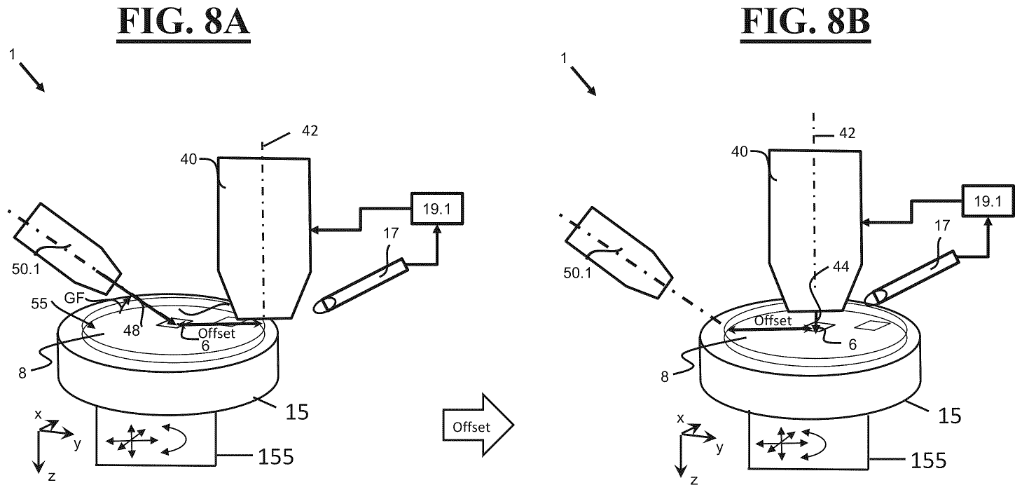

FIG. 7 illustrates a second workflow according to the disclosure and FIGS. 8A-8B schematically illustrate a dual beam device 1 suited for carrying out the second workflow. Contrary to the first workflow, wherein the coincidence point is still used during the milling, the coincidence point is given up completely in the second workflow. Instead of a coincidence arrangement, an offset arrangement of the two columns 50.1, 40 is applied: According to the depicted offset arrangement, the FIB column optical axis 48 and the CPB optical axis 42 intersect a wafer surface 55 at two different points or positions, the difference between the two different positions defining an offset level with the wafer top surface 55 that is indicated by a double arrow. This offset allows independently setting the working distances of the FIB column 50.1 and of the CPB imaging column 40 without geometric constraints due to the shapes and/or positions of the FIB column 50.1 and the CPB imaging column 40. Therefore, optimum working distances can be set for both the FIB column 50.1 and for the CPB imaging column 40. However, it is desirable to relatively move the wafer with respect to the two columns 50.1, 40 according to the offset before either imaging or milling is carried out. A possibility for this relative movement is a stage move, for example a lateral stage move (y-direction in the depicted example).

It is noted that an offset can be set with flexibility inside certain ranges. Practically, the offset has a minimum size at which the columns 50.1 and 40 cannot block each other anymore. However, the offset can be made bigger than this minimum size. It is therefore desirable to adjust an offset to a distance between two measurement sites 6 on a wafer 8. Then, it becomes possible to mill a first measurement site and to image a second measurement site. Applying further columns can even more parallelize milling and imaging. It is also possible to rotate the stage 155 (or at least the wafer support table 15) to switch between two measurement sites 6. This also allows for parallelizing milling and imaging of two measurement sites 6.

FIG. 7 summarizes an exemplary workflow: In step S10 a focused ion beam (FIB) column 50.1 and a charged particle beam (CPB) imaging column 40 are provided in an offset arrangement; both working distances can be chosen optimum. In step S11 a cross section surface layer is removed at a first measurement site 6 of the wafer 8 using the FIB column 50.1 to make a new cross section accessible for imaging. In step S12 the wafer surface is relatively moved, for example by a lateral stage movement or by a stage rotation according to the offset. In step S13 the new cross section of the first measurement site 6 of the wafer 8 is imaged with the CPB imaging column 40. In step S14 the wafer 8 is relatively moved (back) according to the offset again. Then in step S11 the next cross section surface layer can be removed and steps S12 to S14 are repeated. The process ends for example in step S15 when the complete site 6 has been milled and imaged. Then, another site 6 can be milled and imaged. As already described above, if the offset is adjusted to a distance between different measurement sites 6, the process can be also parallelized.

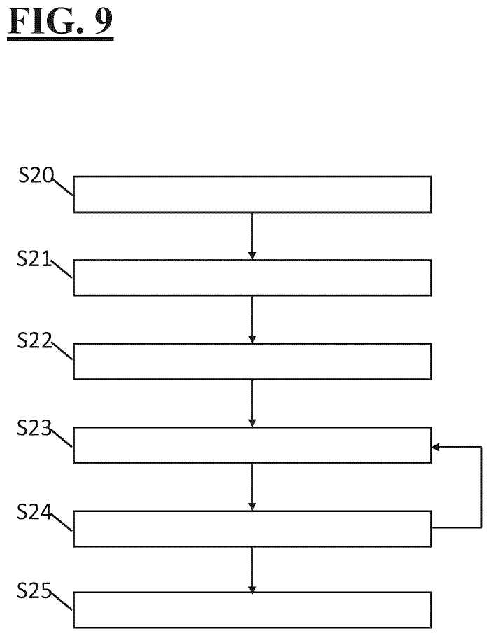

FIG. 9 illustrates a third workflow according to the disclosure. In a step S20 a focused ion beam (FIB) column 50.1 and a charged particle beam (CPB) imaging column 40 are provided in a coincidence arrangement. In step S21 either an optimized working distance for the FIB column and a tradeoff working distance for the CPB imaging column are determined or a tradeoff working distance for the FIB column and an optimized working distance for the CPB imaging column are determined. In step S22 the FIB column is moved along its optical axis to arrange the FIB column in its determined working distance (which is either optimized or tradeoff) and/or the CPB imaging column is moved along its optical axis to arrange the CPB imaging column in its determined working distance (which is either tradeoff or optimized). In step S23 a cross section surface layer is removed at the measurement site of the wafer 8 using the FIB column 50.1 arranged in its working distance to make a new cross section accessible for imaging. In step S24 the new cross section at the measurement site 6 of the wafer 8 is imaged with the CPB imaging column 40 arranged in its working distance. Milling and imaging (steps S23 and S24) can be repeated. In step S25 the process ends. The working distances of the FIB column and of the CPB imaging column are not both optimum at the same time; but one of them is chosen optimum (which means best under the given circumstances or constraints) and the other one is chosen as good as still possible under the given circumstances and constraints which now include the optimized and therefore given working distance of the other column. For example, if in a use case in which the imaging resolution is of higher importance than the milling quality, the working distance of the CPB imaging column 40 can be reduced at the price of decreasing the working distance of the FIB column 50.1. An algorithm for determining the tradeoff working distances can be applied.

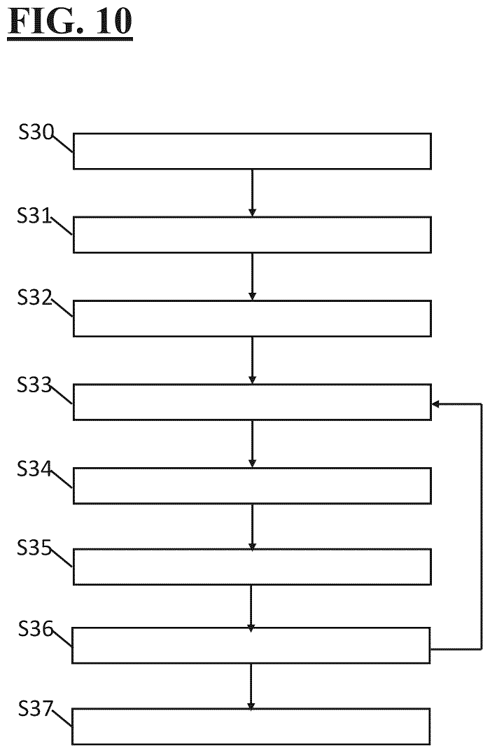

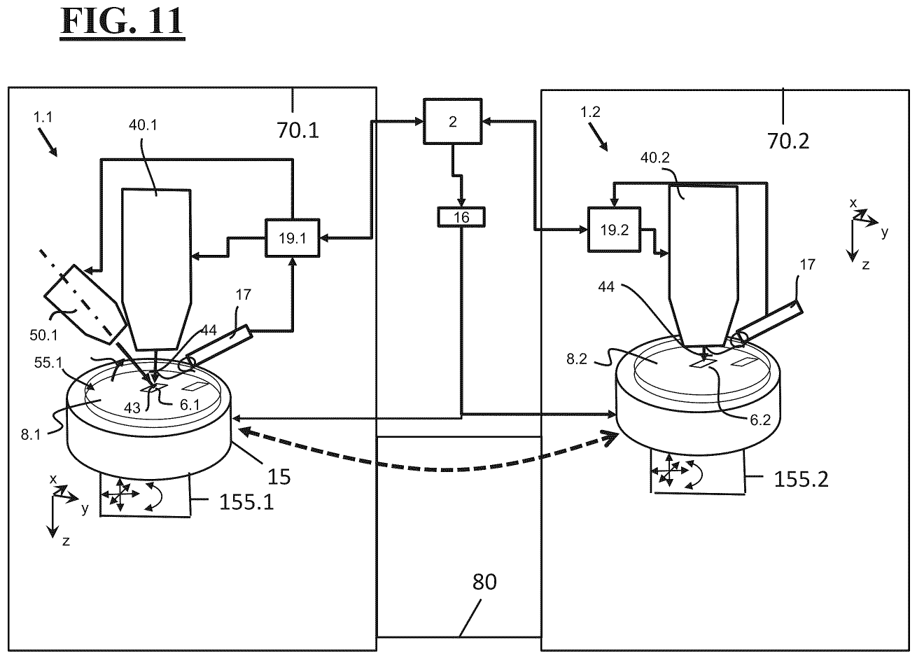

FIG. 10 illustrates a fourth workflow according to the disclosure and FIG. 11 schematically illustrates a dual chamber system suited for carrying out the fourth workflow. The dual chamber system comprises a first chamber 70.1 and a second chamber 70.2. According to this dual chamber solution, milling and high-resolution imaging a spatially separated. In the first chamber 70.1, milling is carried out. In the second chamber 70.2 imaging with high-resolution is carried out. The wafer 8 is transferred between the two chambers 70.1, 70.2 so that milling and high-resolution imaging can be carried out alternatingly.

In more detail, the first chamber 70.1 comprises a dual beam system 1.1 with a FIB column 50.1 and a CPB imaging column 40.1 that are arranged according to a coincidence arrangement. However, the CPB imaging column 40.1 is not used for imaging the cross sections as such, but is applied for supervising/monitoring the milling process with the FIB 50.1, only. For this supervising or monitoring purpose a lower imaging resolution is normally sufficient. Therefore, the working distance of the FIB column 50.1 can be optimized at the price of imaging resolution (bigger working distance) of the CPB imaging column 40.

When a cross section surface layer is readily milled, the wafer 8 is transferred into the second chamber 70.2 for high-resolution imaging. According to the depicted example, the second chamber 70.2 comprises a high-resolution CPB imaging device 40.2. In general, this device 40.2 can be identical to the device 40.1 in the first chamber; however, since the working distance can be optimized, the imaging resolution will be better. Still, it is desirable to apply a different and more advanced CPB imaging device 40.2 in the second chamber 70.2 than in the first chamber 70.1. Examples are a high-resolution scanning electron microscope (SEM), a corrected SEM with an additional electrostatic lens for reducing imaging aberrations or a multi-beam scanning electron microscope (MultiSEM or mSEM).

The transfer of the wafer 8 between the two chambers 70.1 and 70.2 can be realized in different ways. One possibility is to transfer the wafer support table 15, according to which the wafer 8 is already registered. Alternatively, it is possible to transfer the complete stage 155.1. from one chamber to the other chamber. This approach can be even further improved if a second stage 155.2 is applied: It is then possible to parallelize work on two wafers 8.1 and 8.2. While one wafer 8.1 is for example milled in the first chamber 70.1, the second wafer 8.2 can be imaged in the second chamber 70.2 and vice versa. The stage exchange can be carried out via a stage transfer interface 80. Optionally, this transfer interface 80 h can be provided with one or two vacuum locks (not shown), for example, to keep out the mill deposition material from the imaging or second chamber 70.2.

FIG. 10 exemplary summarizes a possible workflow for a method for obtaining a sequence of first cross-section images of a first measurement site 6.1 situated on a first wafer 8.1 and for obtaining a sequence of second cross-section images of a second measurement site 6.2 situated on a second wafer 8.2. In step S30 a first wafer 8.1 is provided on a first stage 155.1 and the first wafer 8.1 is registered on the first stage 155.1. Ins Step S31 a second wafer 8.2 is provided on a second stage 155.2 and the second wafer 8.2 is registered on the second stage 155.2. In step S32 a first cross section surface layer of the first measurement site 6.1 of the first wafer 8.1 is removed using the FIB column 50.1 working at a set FIB working distance to make a first new cross section accessible for imaging. In step S33 the positions of the first stage 155.1 and the second stage 155.2 are exchanged. In step S34 the first new cross section at the first measurement site 6.1 of the first wafer 8.1 is imaged with the CPB imaging column 40.2 at a set working distance and simultaneously a second cross section surface layer of the second measurement site 6.2 of the second wafer 8.2 is milled using the FIB column 50.1 at the set FIB working distance to make a second new cross section accessible for imaging. In step S35 the positions of the first stage 155.1 and the second stage 155.2 are changed again and the wafers 8.1 and 8.2 are transferred from chamber to chamber, respectively. In step S36 the second new cross section at the second measurement site 6.2 of the second wafer 8.2 is imaged with the CPB imaging column 40.2 at the set working distance and simultaneously another first cross section surface layer of the first measurement site 6.1 of the first wafer 8.1 is removed using the FIB column 40.1 at the set FIB working distance to make another first new cross section accessible for imaging.

The steps S33 to S36 can be repeated until the two measurement sites 6.1 and 6.2 are completely milled and imaged. In step S37 the exemplary process ends. It is also possible to sequentially mill and sequentially image a plurality of measurement sites 6 on each wafer 8.1, 8.2. In this scenario the transfer times from chamber 70.1 to chamber 70.2 can be kept even lower and the overall process becomes faster.

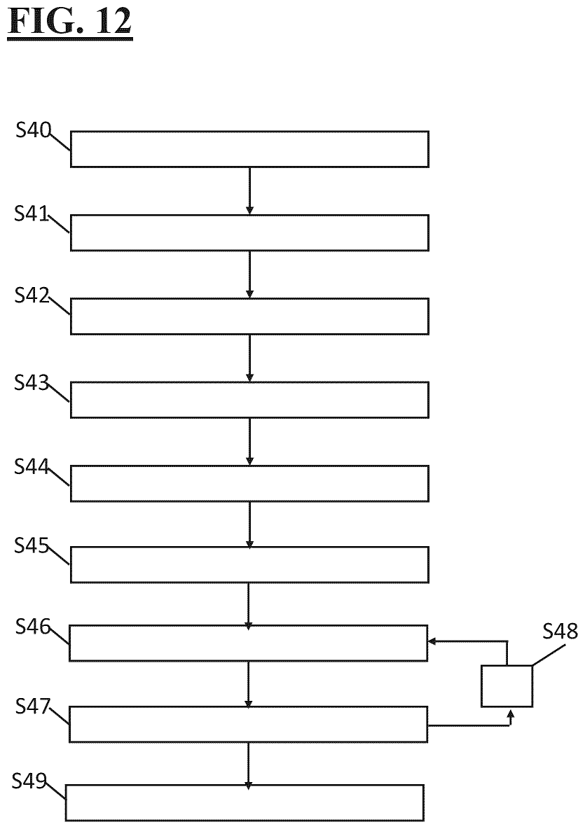

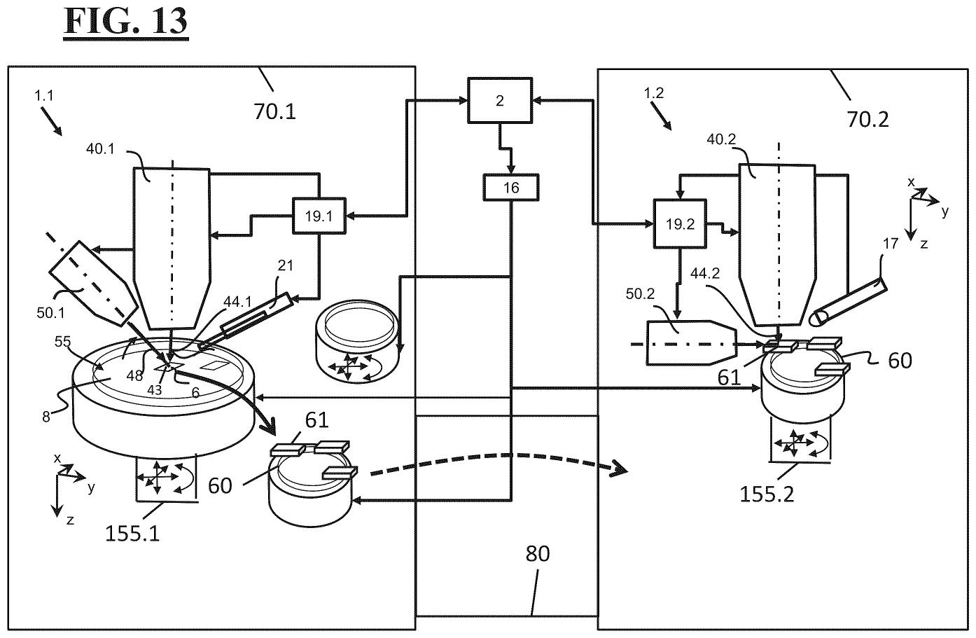

FIG. 12 illustrates a fifth workflow according to the disclosure and FIG. 13 schematically illustrates a dual chamber system suited for carrying out the fifth workflow.

The first chamber 70.1 comprises a first focused ion beam (FIB) column 50.1 and a first charged particle beam (CPB) imaging column 40.1 which are arranged in a wedge-cut coincidence arrangement. The chamber 70.1 further comprises a first stage 155.1 on which a wafer 8 with several measurement sites 6 is positioned. The first chamber 70.1 is used for sample preparation, only. This sample preparation comprises the extraction of 3D blocks or chunks 61 from the wafer: The first FIB column 50.1 is used for milling around the measurement sites 6, it is not used for slice removal. The first CPB imaging column 40.1 is only used for supervising the milling around; therefore, a comparatively low imaging resolution of the first CPB imaging column 40.1 is sufficient. According to this example, the first chamber 70.1 furthermore comprises a manipulator 21 for lifting-out chunks 61 milled from the wafer 8. The manipulator 21 can arrange one or several chunks 61 on a sample holder 60, wherein the chunks 61 are placed at an edge of the sample holder 60. Milling, lift-out and chunk positioning can be controlled directly or indirectly by an operation control unit 2.

The one or more chunks 61 placed on the sample holder 60 can then be transferred from the first chamber 70.1 to the second chamber 70.2 for milling and imaging. The transfer can take place via a sample transfer interface 80 with two vacuum locks, for example. It is possible that the sample holder 60 with the chunks 61 is transferred as such and then placed on a second stage 155.2 in the second chamber 70.2. However, it is also possible to transfer the holder 60 together with a respectively arranged stage (not shown in FIG. 13). It is also possible to provide more than one sample holder 60. The provision of more than one sample holder 60 can contribute to process parallelization: During the placement of the chunks 61 on a first holder 60 in a first chamber 70.1, for example, the chunks 61 placed on a second holder 60 can already be imaged in the second chamber 70.2.

In the present example, the second chamber 70.2 comprises a second FIB column 50.2 and a second CPB imaging columns 40.2 in a coincidence arrangement. Since the measurement sites 6 have been extracted and positioned at an edge of the sample holder 60, a high-resolution arrangement of FIB column 50.2 and CPB columns 40.2 can be used that allows for an edge-cut. Milling with the FIB column 50.2 can be alternated with high-resolution imaging by the CPB imaging column 40.2 in a way generally known in the art. Further details have been explained with respect to FIG. 1, for example.

It is another possibility to provide a further chamber (not shown) with an additional FIB/CPB arrangement applied for milling and high-resolution imaging. This allows for further speed up a workflow.

An exemplary workflow for obtaining at least one sequence of parallel cross-section images of at least one measurement site 6 of a wafer 8 is depicted in FIG. 12: In step S40 a first focused ion beam (FIB) column 50.1 and a first charged particle beam (CPB) imaging column 40.1 are provided in a wedge-cut coincidence arrangement in a first chamber 70.1, in this coincidence arrangement a FIB optical axis 48 of the FIB column 50.1 and a CPB optical axis 42 of the CPB imaging column 40.1 coinciding at a wafer surface 8 and forming an arrangement angle GFE between the FIB optical axis and the CPB optical axis.

In step S41 a second FIB column 50.2 and a second CPB imaging column 40.2 are provided in an edge-cut coincidence arrangement in a second chamber 70.2, in this edge-cut coincidence arrangement a FIB optical axis of the second FIB column and a CPB optical axis of the second CPB imaging column coinciding at a wafer 8 or sample surface 55 and being perpendicular to one another, the optical axis of the second CPB column 40.2 being arranged perpendicular to the wafer or sample surface 55 and the second CPB column 40.2 being arranged at a short working distance allowing for high-resolution imaging.

In step S42 the first wafer 8 with at least one measurement site 6 is registered on a first stage 155.

In step S43 it is milled around the at least one measurement site 6 with first FIB column 50.1 in the first chamber 70.1, thus generating at least one chunk 61, and the milling is supervised with the first CPB imaging column 40.1 in the first chamber 70.1.

In step S44 the at least chunk 61 is lifted-out from the wafer 8 and the at least one chunk 61 is arranged on a sample holder 60 in such a way that a measurement site 6 of each chunk 61 is placed at an edge of the sample holder 60.

In step S45 the sample holder 60 with the at least one chunk 61 is transferred into the second chamber 70.2.

In step S46 the at least one measurement site 6 included in the at least one chunk 61 is registered on the second stage 155.2.

In step S47 at least one sequence of parallel cross-section images of the at least one measurement site 6 is obtained by repeatedly milling the at least one chunk 61 with the second FIB column 50.2 and repeatedly imaging the at least one chunk 61 with the second CPB column 40.2 in the second chamber 70.2. Here, due to the geometric arrangement of the chunks 61, high-resolution imaging is possible.

In optional step S48 the second stage 155.2 is rotated to make a second measurement site 6.2 located on a second chunk 61 accessible for milling and imaging.

Optionally, a plurality of sample holders 60 and sequentially handling the plurality of sample holders 60 in the first chamber 70.1 and in the second chamber 70.2 according to steps S43 to S47 can be carried out.

The person skilled in the art will be aware of other workflows and systems without departing from the scope of the disclosure which is defined by the claims.

In the following, examples of the disclosure will be provided.

Example 1. A method for obtaining a sequence of cross-section images of a measurement site of a wafer parallel to one another, comprising the following steps:
1a) providing a focused ion beam (FIB) column and a charged particle beam (CPB) imaging column in a coincidence arrangement, in this coincidence arrangement a FIB optical axis of the FIB column and a CPB optical axis of the CPB imaging column coinciding at a wafer surface and forming an arrangement angle GFE between the FIB optical axis and the CPB optical axis;
1b) in the coincidence arrangement removing a cross section surface layer of measurement site of a wafer using the FIB column to make a new cross section accessible for imaging;
1c) reducing a working distance between the CPB imaging column and the wafer surface in a direction along the axis of the CPB imaging column;
1d) imaging the new cross section at the measurement site of the wafer with the CPB imaging column at the reduced working distance and thus not in the coincidence arrangement;

1e) increasing the working distance between the CPB imaging column and the wafer surface in the direction along the axis of the CPB imaging column until the coincidence arrangement is reached.

Example 2. The method of example 1, wherein the sequence of method steps 1b), 1c) 1d) and 1e) is carried out repeatedly.

Example 3. The method of example 1, further comprising in the coincidence arrangement imaging the removal of the cross-section surface layer with the CPB imaging column.

Example 4. The method of example 1, wherein reducing the working distance between the CPB imaging column and the wafer surface comprises moving a stage carrying the semiconductor sample, in particular vertically moving the stage.

Example 5. The method of example 4, wherein the CPB optical axis is aligned with the normal of the wafer surface.

Example 6. The method of example 1, wherein the following relation holds for the arrangement angle GFE: 30°≤GFE≤45°, in particular 30°≤GFE≤40° or 30°≤GFE≤35°.

Example 7. The method of example 1, wherein reducing the working distance between the PCB imaging column comprises moving the PCB imaging column along the PCB optical axis.

Example 8. Computer program product with a program code adapted for executing the method according to example 1.

Example 9. A one-chamber system, comprising:

a focused ion beam (FIB) column and a charged particle beam (CPB) imaging column adapted to be arranged in a coincidence arrangement, in this coincidence arrangement a FIB optical axis of the FIB column and a CPB optical axis of the CPB imaging column coinciding at a wafer surface and forming an arrangement angle GFE between the FIB optical axis and the CPB optical axis, wherein the CPB optical axis is arranged in a direction perpendicular to the wafer surface;

a stage adapted for carrying a wafer and configured to be movable in a direction perpendicular to the wafer surface; and a control; wherein the control is configured for controlling the FIB column, the CPB imaging column and the stage for carrying out the method of example 1.

Example 10. A method for obtaining a sequence of cross-section images of a measurement site of a wafer parallel to one another, wherein the wafer is carried by a stage, the method comprising the following steps:
2a) providing a focused ion beam (FIB) column and a charged particle beam (CPB) imaging column in an offset arrangement, wherein in this offset arrangement the FIB column optical axis and the CPB optical axis intersect a wafer surface at two different positions, the difference between the two different positions defining an offset on the wafer surface, this offset allowing independently setting of working distances of the FIB column and of the CPB imaging column without geometric constraints due to the shapes and/or positions of the FIB column and the CPB imaging column;
2b) removing a cross section surface layer at a first measurement site of the wafer using the FIB column to make a new cross section accessible for imaging;
2c) moving the wafer surface by a stage movement relative to the FIB column and the CPB imaging column according to the offset;
2d) imaging the new cross section of the first measurement site of the wafer with the CPB imaging column.

Example 11. The method of example 10, further comprises
2e) moving the wafer surface by a stage movement relative to the FIB column and the CPB imaging column according to the offset.

Example 12 The method of example 11, wherein the sequence of method steps 2b), 2c), 2d) and 2e) is carried out repeatedly.

Example 13. The method according to example 10 wherein the relative movement comprises a lateral stage movement or a stage rotation.

Example 14. The method according to example 10, wherein a working distance of the FIB column is optimized and/or wherein a working distance of the CPB imaging column is optimized.

Example 15. The method according to example 10, wherein the offset matches a distance between the first measurement site on the wafer surface and a second measurement site on the wafer surface.

Example 16. The method according to example 15,
further comprising obtaining a sequence of cross-section images of the second measurement site of a wafer parallel to one another by repeatedly carrying out the sequence of method steps 2b), 2c) and 2d) at the second measurement site,
wherein the step of removing a cross section surface layer at the second measurement site of the wafer is carried out simultaneously with imaging the new cross section of the first measurement site of the wafer with the CPB imaging column and
wherein the step of removing a cross section surface layer at the first measurement site of the wafer is carried out simultaneously with imaging the new cross section of the second measurement site of the wafer with the CPB imaging column.

Example 17. Computer program product with a program code adapted for executing the method according to example 10.

Example 18. A one-chamber system, comprising:
a focused ion beam (FIB) column and a charged particle beam (CPB) imaging column adapted to be arranged in an offset arrangement, wherein in this offset arrangement the FIB optical axis and the CPB optical axis intersect a wafer surface at two different positions, the difference between the two different positions defining an offset on the wafer surface, this offset having a size big enough for allowing an independent setting of working distances of the FIB column and of the CPB imaging column without geometric constraints due to the shapes and/or positions of the FIB column and the CPB imaging column;
a stage adapted for carrying a wafer and configured to be movable within a plane parallel to the wafer surface; and
a control;
wherein the control is configured for controlling the FIB device, the CPB imaging device and the stage for carrying out the method of example 10.

Example 19. A method for obtaining a sequence of cross-section images of a measurement site of a wafer parallel to one another, comprising the following steps:
3a) providing a focused ion beam (FIB) column and a charged particle beam (CPB) imaging column in a coincidence arrangement, in this coincidence arrangement a FIB optical axis of the FIB column and a CPB optical axis of the CPB imaging column coinciding at a wafer surface and forming an arrangement angle GFE between the FIB optical axis and the CPB optical axis;
3b) determining either an optimized working distance for the FIB column and a tradeoff working distance for the CPB imaging column or determining a tradeoff working distance for the FIB column and an optimized working distance for the CPB imaging column;
3c) moving the FIB column along its optical axis to arrange the FIB column in its determined working distance and/or moving the CPB imaging column along its optical axis to arrange the CPB imaging column in its determined working distance
3d) removing a cross section surface layer at the measurement site of the wafer using the FIB column arranged in its working distance to make a new cross section accessible for imaging; and
3e) imaging the new cross section at the measurement site of the wafer with the CPB imaging column arranged in its working distance.

Example 20. The method of example 19, wherein the sequence of method steps 3d) and 3e) is carried out repeatedly.

Example 21. The method of example 19, wherein step 3c) comprises:
decreasing the working distance of the FIB column and increasing the working distance of the CPB imaging column, or
increasing the working distance of the FIB column and decreasing the working distance of the CPB imaging column.

Example 22. Computer program product with a program code adapted for executing the method according to example 19.

Example 23. A one-chamber system, comprising:
a focused ion beam (FIB) column and a charged particle beam (CPB) imaging column adapted to be arranged in a coincidence arrangement, in this coincidence arrangement a FIB optical axis of the FIB column and a CPB optical axis of the CPB imaging column coinciding at a wafer surface and forming an arrangement angle GFE between the FIB optical axis and the CPB optical axis,
wherein the FIB column is configured to be movable along its FIB optical axis and wherein the CPB imaging column is configured to be movable along its CPB optical axis;
a stage adapted for carrying a wafer; and
a control;
wherein the control is configured for controlling the FIB column, the CPB imaging column and the stage for carrying out the method of example 19.

Example 24. A method for obtaining a sequence of first cross-section images of a first measurement site situated on a first wafer and for obtaining a sequence of second cross-section images of a second measurement site situated on a second wafer, comprising:
4a) Providing a first wafer on a first stage and registering the first wafer on the first stage;
4b) Providing a second wafer on a second stage and registering the second wafer on the second stage;
4c) Removing a first cross section surface layer of the first measurement site of the first wafer using the FIB column working at a set FIB working distance to make a first new cross section accessible for imaging;
4d) Exchanging the positions of the first stage and the second stage;
4e) Imaging the first new cross section at the first measurement site of the first wafer with the CPB imaging column at a set working distance and simultaneously removing a second cross section surface layer of the second measurement site of the second wafer using the FIB column at the set FIB working distance to make a second new cross section accessible for imaging;
4f) Exchanging the positions of the first stage and the second stage;
4g) Imaging the second new cross section at the second measurement site of the second wafer with the CPB imaging column at the set working distance and simultaneously removing another first cross section surface layer of the first measurement site of the first wafer using the FIB column at the set FIB working distance to make another first new cross section accessible for imaging.

Example 25. The method of example 24, wherein the sequence of method steps 4d), 4e), 4f) and 4g) is carried out repeatedly.

Example 26. The method of example 24,
wherein a plurality of first measurement sites on the first wafer are sequentially milled and sequentially imaged; and
wherein a plurality of second measurement sites on the second wafer are sequentially milled and sequentially imaged.

Example 27. The method of example 24,
wherein removing the first or/and second cross section layer surface is supervised by low-resolution imaging; and/or
wherein imaging the new first or/and second cross section comprises high-resolution imaging.

Example 28. The method of example 27,
wherein low-resolution imaging is carried out with the FIB column used for removing the first and second cross section surface layers or with a low-resolution scanning electron microscope (SEM) arranged in a cross-beam arrangement with the FIB column used for removing the first and second cross section surface layers; and/or
wherein high-resolution imaging is carried out with a high-resolution scanning electron microscope (SEM), a helium ion microscope (HIM) or a multibeam scanning electron microscope (MultiSEM).

Example 29. The method of example 24, wherein exchanging the positions of the first stage and the second stage comprises transferring registration information.

Example 30. The method of example 24,
wherein the FIB column is arranged in a first chamber and wherein the CPB imaging column is arranged in a second chamber.

Example 31. The method of example 30,
wherein exchanging the position of the first and second stage comprises transferring one of the stages from the first chamber to the second chamber and vice versa.

Example 32. Computer program product with a program code adapted for executing the method according to example 24.

Example 33. A dual chamber system, comprising:
a first chamber with a focused ion beam (FIB) column and a low resolution charged particle beam (CPB) imaging column adapted to be arranged in a wedge-cut coincidence arrangement, in this coincidence arrangement a FIB optical axis of the FIB column and a CPB optical axis of the low resolution CPB imaging column coinciding at a wafer surface and forming an arrangement angle GFE between the FIB optical axis and the CPB optical axis;
a second chamber with a high-resolution CPB imaging column, its optical axis being arranged perpendicular to a wafer surface;
a first stage for carrying a first wafer;
a second stage for carrying a second wafer;
a stage exchange mechanism configured for exchanging the positions of the first stage and the second stage; and a control,
wherein the control is configured for controlling the first chamber with the FIB column and the low resolution CPB imaging column, the second chamber with the high-resolution CPB imaging column, the first stage, the second stage and the stage exchange mechanism for carrying out the method of example 28.

Example 34. A method for obtaining at least one sequence of parallel cross-section images of at least one measurement site of a wafer, comprising the following steps:
5a) providing a first focused ion beam (FIB) column and a first charged particle beam (CPB) imaging column in a wedge-cut coincidence arrangement in a first chamber, in this coincidence arrangement a FIB optical axis of the FIB column and a CPB optical axis of the CPB imaging column coinciding at a wafer surface and forming an arrangement angle GFE between the FIB optical axis and the CPB optical axis;
5b) providing a second FIB column and a second CPB imaging column in an edge-cut coincidence arrangement in a second chamber, in this edge-cut coincidence arrangement a FIB optical axis of the second FIB column and a CPB optical axis of the second CPB imaging column coinciding at a wafer or sample surface and being perpendicular to one another, the optical axis of the second CPB column being arranged perpendicular to the wafer or sample surface and the CPB column being arranged at a short working distance allowing for high-resolution imaging;
5c) registering the first wafer with at least one measurement site on a first stage;
5d) milling around the at least one measurement site with first FIB column in the first chamber, thus generating at least one chunk, and supervising the milling with the first CPB imaging column in the first chamber;
5e) lifting-out the at least chunk from the wafer and arranging the at least one chunk on a sample holder in such a way that a measurement site of each chunk is placed at an edge of the sample holder;
5f) transferring the holder with the at least one chunk into the second chamber;
5g) registering the at least one measurement site included in the at least one chunk on the second stage;
5h) obtaining at least one sequence of parallel cross-section images of the at least one measurement site by repeatedly milling the at least one chunk with the second FIB column and repeatedly imaging the at least one chunk with the second CPB column in the second chamber.

Example 35. The method of example 34, further comprising:
5i) moving the second stage to make a second measurement site accessible for milling and imaging.

Example 36. The method of example 34, further comprising providing a plurality of sample holders and sequentially handling the plurality of sample holders in the first chamber and in the second chamber according to steps 5d) to 5h).

Example 37. A computer program product with a program code adapted for executing the method according to example 34.

Example 38. A dual chamber system, comprising:
a first chamber, comprising
   a first focused ion beam (FIB) column and a first charged particle beam (CPB) imaging column adapted to be arranged in a wedge-cut coincidence arrangement, in this wedge-cut coincidence arrangement a FIB optical axis of the FIB column and a CPB optical axis of the low resolution CPB imaging column coinciding at a wafer surface and forming an arrangement angle GFE between the FIB optical axis and the CPB optical axis;
   a first stage for carrying a wafer;
   a sample holder adapted for carrying at least one chunk,
   a manipulator configured for lifting-out chunks milled from the wafer and configured for placing the chunks on the sample holder;
a second chamber, comprising
   a second FIB column and a second CPB imaging column in an edge-cut coincidence arrangement, in this edge-cut coincidence arrangement a FIB optical axis of the second FIB column and a CPB optical axis of the second CPB imaging column coinciding at a wafer or sample surface and being perpendicular to one another, the optical axis of the second CPB column being arranged perpendicular to the wafer or sample surface and the second CPB column being arranged at a short working distance allowing for high-resolution imaging;
   a second stage adapted for carrying the sample holder;
a sample holder transfer mechanism configured for transferring the sample holder from the first chamber to the second chamber and for placing the sample holder on the second stage; and
a control,
wherein the control is configured for the first chamber with the first FIB column, the first CPB imaging column, the first stage, the sample holder and the manipulator, the second chamber with the second chamber with the second FIB column, the second CPB imaging column and the second stage, and the sample holder transfer mechanism for carrying out the method of example 34.

### LIST OF REFERENCE SIGNS

1 Dual Beam Device

2 Operation Control Unit

4 first cross-section image features

6 measurement sites

8 wafer

10 sample (for example extracted from wafer)

15 wafer support table

16 stage control unit

17 Secondary Electron detector

19 Control Unit

21 manipulator

40 charged particle beam (CPB) imaging column

42 Optical Axis of imaging system

43 Intersection point

44 Imaging charged particle beam

46 scan path

48 Fib Optical Axis

49 bottom edge

50 FIB column

51 focused ion beam

52 cross-section surface

53 cross-section surface

54 cross-section surface

55 wafer top surface

60 sample holder

61 chunk

70 chamber

80 transfer interface

100 cross-section image slice

155 wafer stage

160 inspection volume

307 measured cross-section image of HAR structure

311 cross-section image slice

313 word lines

315 edge with surface

500 wafer inspection system

1000 sequence of 2D image slices

L.1 . . . L.M layers

d distance between adjacent cross sections or adjacent cross-section image slices

GF milling angle (angle between wafer surface and FIB axis at intersection point)

GE imaging angle (angle between CPB imaging system axis and normal to wafer surface at intersection point)

GFE arrangement angle (angle between FIB axis and CPB imaging system axis)

GFE1 arrangement angle (angle between FIB axis and CPB imaging system axis)

GFE2 arrangement angle (angle between FIB axis and CPB imaging system axis)

WD1 working distance

WD2 working distance

WD3 working distance

dz height difference, stage move

h height

h′ height

Pos1 position 1 during milling

Pos 2 position 2 during high resolution imaging

α_{FIB} opening angle FIB column

α_{CPB} opening angle CPB imaging column

1. A method, comprising:
a) providing a focused ion beam (FIB) column and a charged particle beam (CPB) imaging column in a coincidence arrangement in which a FIB optical axis of the FIB column and a CPB optical axis of the CPB imaging column coincide at a surface of a wafer and define an arrangement angle between the FIB optical axis and the CPB optical axis;
after a), b) in the coincidence arrangement, removing a cross section surface layer of a measurement site of the wafer using the FIB column, thereby making a new cross section of the wafer accessible for imaging;
after b), c) reducing a distance between the CPB imaging column and the wafer surface in a direction along the axis of the CPB imaging column;
after c), d) imaging the new cross section of the wafer at the measurement site of the wafer using the CPB imaging column at the reduced distance and not in the coincidence arrangement; and
after d), e) increasing the distance between the CPB imaging column and the wafer surface in the direction along the axis of the CPB imaging column until the coincidence arrangement is reached.

2. The method of claim 1, further comprising repeatedly performing the sequence of b), c), d) and e).

3. The method of claim 1, wherein b) further comprises imaging the removal of the cross-section surface layer using the CPB imaging column.

4. The method of claim 1, wherein c) comprises moving a stage carrying the wafer.

5. The method of claim 1, wherein the CPB optical axis is aligned with a normal of the wafer surface.

6. The method of claim 1, wherein the FIB optical axis is arranged at a slant angle with respect to a top surface of the wafer.

7. The method of claim 1, wherein the arrangement angle is at least 30° and at most 45°.

8. The method of claim 1, wherein c) comprises moving the PCB imaging column along the PCB optical axis.

9. One or more machine-readable hardware storage devices comprising instructions that are executable by one or more processing devices to perform operations comprising the method of claim 1.

10. A system, comprising:
one or more processing devices; and
one or more machine-readable hardware storage devices comprising instructions that are executable by one or more processing devices to perform operations comprising the method of claim 1.

11. The system of claim 10, wherein the system is a one-chamber system, comprising:
the FIB column;
the CPB imaging column; and
a stage configured to carry the wafer, the stage being movable in a direction perpendicular to the wafer surface.

12. A method, comprising:
a) providing a focused ion beam (FIB) column and a charged particle beam (CPB) imaging column in an offset arrangement in which a FIB column optical axis and a CPB optical axis intersect a surface of a wafer surface at first and second different positions, a difference between the first and second different positions defining an offset on the wafer surface, the offset configured to allow independent setting of working distances of the FIB column and of the CPB imaging column without geometric constraints due to shapes and/or positions of the FIB column and the CPB imaging column;
after a), b) removing a cross section surface layer of the wafer at a first measurement site of the wafer using the FIB column, thereby making a new cross section accessible for imaging;
after b), c) moving the wafer surface by moving a stage relative to the FIB column and the CPB imaging column according to the offset; and
after c), d) imaging the new cross section of the wafer at the first measurement site using the CPB imaging column.

13. The method of claim 12, further comprising moving the wafer surface by moving the stage relative to the FIB column and the CPB imaging column according to the offset.

14. The method of claim 13, further comprising repeatedly performing the sequence of b), c), d) and e).

15. The method of claim 13, wherein the relative movement of the stage comprises laterally moving the stage or rotating the stage.

16. The method of claim 13, wherein a working distance of the FIB column is optimized, and/or wherein a working distance of the CPB imaging column is optimized.

17. The method of claim 13, wherein the offset matches a distance between the first measurement site on the wafer surface and a second measurement site on the wafer surface.

18.-22. (canceled)

23. A method, comprising:
a) providing a focused ion beam (FIB) column and a charged particle beam (CPB) imaging column in a coincidence arrangement in which a FIB optical axis of the FIB column and a CPB optical axis of the CPB imaging column coincide at a wafer surface and define an arrangement angle between the FIB optical axis and the CPB optical axis;
after a), b) determining an optimized working distance for the FIB column and a tradeoff working distance for the CPB imaging column, or determining a tradeoff working distance for the FIB column and an optimized working distance for the CPB imaging column;
after b), c) moving the FIB column along its optical axis to arrange the FIB column in its determined working distance and/or moving the CPB imaging column along its optical axis to arrange the CPB imaging column in its determined working distance;
after c), d) removing a cross section surface layer at the measurement site of the wafer using the FIB column arranged in its working distance to make a new cross section accessible for imaging; and
after d, e) imaging the new cross section at the measurement site of the wafer with the CPB imaging column arranged in its working distance.

24.-26. (canceled)

27. A method, comprising:
a) providing a first wafer on a first stage and registering the first wafer on the first stage;
b) providing a second wafer on a second stage and registering the second wafer on the second stage;
c) removing a first cross section surface layer of a first measurement site of the first wafer using a FIB column working at a set FIB working distance to make a first new cross section accessible for imaging;
d) exchanging positions of the first stage and the second stage;
e) imaging the first new cross section at the first measurement site of the first wafer with a CPB imaging column at a set working distance and simultaneously removing a second cross section surface layer of the second measurement site of the second wafer using the FIB column at the set FIB working distance to make a second new cross section accessible for imaging
f) exchanging positions of the first stage and the second stage; and
g) imaging the second new cross section at the second measurement site of the second wafer with the CPB imaging column at the set working distance and simultaneously removing another first cross section surface layer of the first measurement site of the first wafer using the FIB column at the set FIB working distance to make another first new cross section accessible for imaging.

28.-30. (canceled)

31. A method, comprising:
a) in a first chamber, providing a first focused ion beam (FIB) column and a first charged particle beam (CPB) imaging column in a wedge-cut coincidence arrangement in which a FIB optical axis of the FIB column and a CPB optical axis of the CPB imaging column coincide at a wafer surface and define an arrangement angle GFE between the FIB optical axis and the CPB optical axis;
b) in a second chamber, providing a second FIB column and a second CPB imaging column in an edge-cut coincidence arrangement in which a FIB optical axis of the second FIB column and a CPB optical axis of the second CPB imaging column coincide at a wafer or sample surface and are perpendicular to one another, the optical axis of the second CPB column being arranged perpendicular to the wafer or sample surface, and the CPB column being arranged at a short working distance to allow high-resolution imaging;
after a), c) registering the first wafer with at least one measurement site on a first stage;
after c), d) milling around the at least one measurement site using the first FIB column in the first chamber to generate at least one chunk, and supervising the milling using the first CPB imaging column in the first chamber;
after d), e) lifting-out the at least one chunk from the wafer and arranging the at least one chunk on a sample holder so that a measurement site of each chunk is placed at an edge of the sample holder;
after e), f) transferring the holder with the at least one chunk to the second chamber;
after f), g) registering the at least one measurement site included in the at least one chunk on the second stage; and
after g), h) obtaining at least one sequence of parallel cross-section images of the at least one measurement site by repeatedly milling the at least one chunk with the second FIB column and repeatedly imaging the at least one chunk with the second CPB column in the second chamber.

32.-34. (canceled)
